(19) United States
(12) Patent Application Publication
(10) Pub. No.: US 2025/0282920 A1
(43) Pub. Date: Sep. 11, 2025

(54) POLYMER FILM, LAMINATE, WIRING BOARD, SILSESQUIOXANE POLYMER, AND POLYMER COMPOSITION

(71) Applicant: FUJIFILM Corporation, Tokyo (JP)

(72) Inventors: Daisuke HAYASHI, Kanagawa (JP); Hiroshi INADA, Kanagawa (JP); Shohei YAMAZAKI, Kanagawa (JP)

(73) Assignee: FUJIFILM Corporation, Tokyo (JP)

(21) Appl. No.: 19/216,746

(22) Filed: May 23, 2025

Related U.S. Application Data
(63) Continuation of application No. PCT/JP2023/038076, filed on Oct. 20, 2023.

(30) Foreign Application Priority Data
Dec. 9, 2022 (JP) 2022-197498
May 26, 2023 (JP) 2023-087306

(51) Int. Cl. C08J 5/18; C08G 77/00; C08G 77/04; C08J 7/04

(52) U.S. Cl. CPC C08J 5/18; C08G 77/045; C08G 77/70; C08J 7/0427; C08J 2367/06; C08J 2377/12; C08J 2383/04

(57) ABSTRACT

A polymer film including a silsesquioxane polymer, in which the polymer film has a dielectric loss tangent of 0.01 or less, and applications thereof.

### CROSS-REFERENCE TO RELATED APPLICATION

This application is a Continuation of International Application No. PCT/JP2023/038076, filed Oct. 20, 2023, which claims priority to Japanese Patent Application No. 2022-197498 filed Dec. 9, 2022 and Japanese Patent Application No. 2023-087306 filed May 26, 2023. Each of the above applications is hereby expressly incorporated by reference, in its entirety, into the present application.

### BACKGROUND OF THE INVENTION

### 1. Field of the Invention

The present disclosure relates to a polymer film, a laminate, a wiring board, a silsesquioxane polymer, and a polymer composition.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent. A copper-clad laminated plate is suitably used as a member constituting a circuit board, and a polymer film is suitably used for producing the copper-clad laminated plate.

For example, JP2021-27307A describes a flexible printed circuit board including a metal layer consisting of one metal, a non-metallic substrate made of a material different from a material of the metal layer, a first modified silicone cured layer directly formed on the non-metallic substrate, a second modified silicone cured layer directly formed on the metal layer, in which both the first modified silicone cured layer and the second modified silicone cured layer contain the following Chemical Formula 1, and a silicone adhesive layer directly bonded to the second modified silicone cured layer and the first modified silicone cured layer, in which the silicone adhesive layer contains the following Chemical Formula 2, and the first modified silicone cured layer, the second modified silicone cured layer, and the silicone adhesive layer contain Chemical Formula 1 and Chemical Formula 2. JP2020-185795A describes a laminate in which a resin film and a metal foil are adhered to each other, in which a siloxane bond is present in an adhesive layer between the resin film and the metal foil, and an interlayer adhesion strength between the resin film and the metal foil, which is measured in accordance with JIS K 6854-2, is 10 N/cm or more. JP2021-054012A describes a laminate for a printed wiring board, which has a substrate containing a thermoplastic resin, a reforming layer located on one surface side of the substrate, an adhesive layer located on a surface side of the reforming layer opposite to the substrate and containing a thermosetting resin, and a metal foil located on a surface side of the adhesive layer opposite to the reforming layer.

### SUMMARY OF THE INVENTION

Typically, a copper-clad laminated plate is produced by laminating a copper foil on a surface of a polymer film. In addition, the wiring board is produced by superimposing a copper-clad laminated plate and a wiring substrate such that a film in the copper-clad laminated plate and the wiring substrate are in contact with each other. In a case of producing a wiring board, from the viewpoint of adhesiveness, it is required that the polymer film deforms by following the step formed on the surface of the wiring substrate.

On the other hand, in a case where a polymer film having excellent step followability with respect to the wiring substrate is used for the copper-clad laminated plate, interlayer peeling may occur in a reflow soldering step performed in a case of mounting an electronic component. Therefore, it has been required to achieve both excellent step followability with respect to the wiring substrate and excellent adhesiveness during reflow soldering (that is, excellent heat resistance).

An object to be achieved by an embodiment of the present invention is to provide a polymer film and a laminate having excellent step followability and excellent heat resistance.

In addition, an object to be achieved by another embodiment of the present invention is to provide a wiring board in which a gap in a vicinity of a wiring pattern is reduced and heat resistance is excellent.

In addition, an object to be achieved by another embodiment of the present invention is to provide a silsesquioxane polymer and a polymer composition, which can be used for a polymer film having excellent step followability and heat resistance.

The means for achieving the above-described objects include the following aspects.
<1>

A polymer film including:
a silsesquioxane polymer,
in which the polymer film has a dielectric loss tangent of 0.01 or less.
<2>

The polymer film according to <1>, in which the polymer film has a dielectric loss tangent of 0.005 or less.
<3>

The polymer film according to <1>, in which the polymer film has a dielectric loss tangent of 0.003 or less.
<4>

The polymer film according to any one of <1> to <3>, in which the polymer film has a storage elastic modulus at 160° C. of 0.5 MPa or less.
<5>

The polymer film according to any one of <1> to <4>, in which the polymer film has a storage elastic modulus A at any temperature from 25° C. to 40° C. of 10⁴ Pa to 10⁸ Pa, and a storage elastic modulus B at any temperature from 150° C. to 250° C. of 10⁶ Pa or less.
<6>

The polymer film according to <5>, in which the storage elastic modulus A is 10⁶ Pa to 10⁸ Pa, and the storage elastic modulus B is 3×10⁵ Pa or less.
<7>

The polymer film according to any one of <1> to <6>, in which the silsesquioxane polymer has a crosslinkable group.
<8>

The polymer film according to <7>, in which the crosslinkable group is at least one selected from the group consisting of a vinyl group, an allyl group, a styryl group, and a maleimide group.
<9>

The polymer film according to any one of <1> to <8>, in which the silsesquioxane polymer has a weight-average molecular weight of 10,000 to 150,000.
<10>

The polymer film according to any one of <1> to <9>, in which the silsesquioxane polymer includes a partial structure represented by Formula (T2) and a partial structure represented by Formula (T3), and a molar ratio of the partial structure represented by Formula (T3) to the partial structure represented by Formula (T2) is 50 or more.

R¹—Si(—OX)O_{2/2} (T2)

R¹—SiO_{3/2} (T3)

In the formula, R's each independently represent an organic group. X represents a hydrogen atom or an alkyl group having 1 to 6 carbon atoms.
<11>

The polymer film according to any one of <1> to <10>, further including a thermoplastic resin or a thermosetting resin other than the silsesquioxane polymer.
<12>

The polymer film according to any one of <1> to <11>, further including an inorganic filler.
<13>

The polymer film according to any one of <1> to <12>, in which the polymer film has a thickness of 10 μm or more.
<14>

The polymer film according to any one of <1> to <13>, in which the polymer film is a bonding sheet.
<15>

A laminate including:
a layer A; and
a layer B disposed on at least one surface of the layer A,
in which the layer B contains a silsesquioxane polymer, and
the laminate has a dielectric loss tangent of 0.01 or less.
<16>

The laminate according to <15>, in which the silsesquioxane polymer has a crosslinkable group.
<17>

The laminate according to <16>, in which the crosslinkable group is at least one selected from the group consisting of a vinyl group, an allyl group, a styryl group, and a maleimide group.
<18>

The laminate according to any one of <15> to <17>, in which the silsesquioxane polymer has a weight-average molecular weight of 10,000 to 150,000.
<19>

The laminate described in any one of <15> to <18>, in which the silsesquioxane polymer includes a partial structure represented by Formula (T2) and a partial structure represented by Formula (T3), and a molar ratio of the partial structure represented by Formula (T3) to the partial structure represented by Formula (T2) is 50 or more.

R¹—Si(—OX)O_{2/2} (T2)

R¹—SiO_{3/2} (T3)

In Formula (T2) and Formula (T3), R¹'s each independently represent an organic group. X represents a hydrogen atom or an alkyl group having 1 to 6 carbon atoms.
<20>

The laminate according to any one of <15> to <19>, in which the layer B further contains a thermoplastic resin or a thermosetting resin other than the silsesquioxane polymer.
<21>

The laminate according to any one of <15> to <20>, in which the layer B further contains an inorganic filler.
<22>

The laminate according to any one of <15> to <21>, in which the layer A contains a liquid crystal polymer.
<23>

The laminate according to <22>, in which the liquid crystal polymer contains an aromatic polyester amide.
<24>

The laminate according to any one of <15> to <23>, in which the layer B has a thickness of 10 μm or more.
<25>

A laminate including a layer A, and a layer B disposed on at least one surface of the layer A, in which the layer B is the polymer film according to any one of <1> to <14>, and the laminate has a dielectric loss tangent of 0.01 or less.
<26>

A wiring board including:
a substrate;
a wiring pattern disposed on at least one surface of the substrate;
a layer B disposed between the wiring patterns and on the wiring pattern; and
a layer A disposed on the layer B,
in which the layer B contains a silsesquioxane polymer, and
the wiring board has a dielectric loss tangent of 0.01 or less.
<27>

The wiring board according to <26>, in which the silsesquioxane polymer includes a partial structure represented by Formula (T2a) and a partial structure represented by Formula (T3a), and a molar ratio of the partial structure represented by Formula (T3a) to the partial structure represented by Formula (T2a) is 70 or more.

R²—Si(—OX)O_{2/2} (T2a)

R²—SiO_{3/2} (T3a)

In the formula, R²'s each independently represent an organic group, and the respective R²'s may be linked to each other. X represents a hydrogen atom or an alkyl group having 1 to 6 carbon atoms.
<28>

The wiring board according to <25> or <26>, in which the layer B further contains a thermoplastic resin or a thermosetting resin other than the silsesquioxane polymer.
<29>

The wiring board according to any one of <26> to <28>, in which the layer B further contains an inorganic filler.
<30>

The wiring board according to any one of <26> to <29>, in which the layer A contains a liquid crystal polymer.
<31>

The wiring board described in <30>, in which the liquid crystal polymer contains an aromatic polyester amide.
<32>

The wiring board according to <26> or <31>, in which a thickness of a thickest portion of the layer B is 10 μm or more.
<33>

A wiring board including:
a substrate;
a wiring pattern disposed on at least one surface of the substrate;
a layer B disposed between the wiring patterns and on the wiring pattern; and
a layer A disposed on the layer B,
in which the layer B is the polymer film according to any one of <1> to <14>, and
the wiring board has a dielectric loss tangent of 0.01 or less.
<34>

A silsesquioxane polymer, in which the silsesquioxane polymer has a dielectric loss tangent of 0.01 or less.
<35>

The silsesquioxane polymer according to <34>, in which the silsesquioxane polymer has a weight-average molecular weight of 4,000 or more.
<36>

The silsesquioxane polymer according to <34> or <35>, in which the silsesquioxane polymer has a dielectric loss tangent of 0.005 or less.
<37>

The silsesquioxane polymer according to <34> or <35>, in which the silsesquioxane polymer has a dielectric loss tangent of 0.003 or less.
<38>

The silsesquioxane polymer according to any one of <34> to <37>, in which the silsesquioxane polymer includes a partial structure represented by Formula (T2) and a partial structure represented by Formula (T3), and a molar ratio of the partial structure represented by Formula (T3) to the partial structure represented by Formula (T2) is 50 or more.

R¹—Si(—OX)O_{2/2} (T2)

R¹—SiO_{3/2} (T3)

In Formula (T2) and Formula (T3), R¹'s each independently represent an organic group. X represents a hydrogen atom or an alkyl group having 1 to 6 carbon atoms.
<39>

The silsesquioxane polymer according to <38>, in which the partial structure represented by Formula (T3) includes a partial structure represented by Formula (T3k) and a partial structure represented by Formula (T3m), and a molar ratio of the partial structure represented by Formula (T3m) to the partial structure represented by Formula (T3k) is 0.01 to 99.

R¹¹—SiO_{3/2} (T3k)

R¹²—SiO_{3/2} (T3m)

In Formula (T3k), R¹¹ is an unsubstituted aromatic hydrocarbon group, an aromatic hydrocarbon group having a substituent, or a vinyl group, and in Formula (T3m), R¹² is an aliphatic hydrocarbon group having a C log P value of 2.5 or more.
<40>

The silsesquioxane polymer according to <39>, in which R¹² is an unsubstituted aliphatic hydrocarbon group having 4 or more carbon atoms, or an aliphatic hydrocarbon group, which has a substituent, having 4 or more carbon atoms.
<41>

The silsesquioxane polymer according to <39>, in which the molar ratio of the partial structure represented by Formula (T3m) to the partial structure represented by Formula (T3k) is 0.25 to 4.
<42>

The silsesquioxane polymer according to any one of <34> to <41>, in which the silsesquioxane polymer has a crosslinkable group.
<43>

The silsesquioxane polymer according to <42>, in which the crosslinkable group is at least one selected from the group consisting of a vinyl group, an allyl group, a styryl group, and a maleimide group.
<44>

The silsesquioxane polymer according to any one of <39> to <41>, in which R¹¹ is a styryl group, and R¹² is an unsubstituted aliphatic hydrocarbon group having 6 or more carbon atoms.
<45>

The silsesquioxane polymer according to any one of <39> to <42>, in which the silsesquioxane polymer has a storage elastic modulus C at any temperature from 25° C. to 40° C. of 10⁴ Pa to 10⁸ Pa, and a storage elastic modulus D at any temperature from 150° C. to 250° C. of 3×10⁵ Pa or less.
<46>

The silsesquioxane polymer according to any one of <39> to <41>, in which R¹¹ is a phenyl group, and R¹² is an unsubstituted aliphatic hydrocarbon group having 6 or more carbon atoms.
<47>

A polymer composition including: the silsesquioxane polymer according to any one of <34> to <46>.
<48>

The polymer composition according to <47>, further including a thermoplastic resin or a thermosetting resin other than the silsesquioxane polymer.
<49>

The polymer composition according to <47> or <48>, further including an inorganic filler.

According to an embodiment of the present invention, there are provided a polymer film and a laminate which have excellent step followability and excellent heat resistance.

In addition, according to another embodiment of the present invention, there is provided a wiring board in which a gap in the vicinity of a wiring pattern is reduced and heat resistance is excellent.

In addition, according to another embodiment of the present invention, there are provided a silsesquioxane polymer and a polymer composition, which can be used for a polymer film having excellent step followability and excellent heat resistance.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

In the present specification, the concept of “(meth)acryl” includes both acryl and methacryl, and the concept of “(meth)acryloyl” includes both acryloyl and methacryloyl.

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, the weight-average molecular weight (Mw) and the number-average molecular weight (Mn) in the present disclosure are molecular weights converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

### [Polymer Film]

The polymer film according to the present disclosure contains a silsesquioxane polymer and has a dielectric loss tangent of 0.01 or less.

As a result of intensive studies, the inventors of the present invention have found that a polymer film having excellent step followability and excellent heat resistance can be provided by adopting the above-described configuration.

The detailed mechanism that brings about the aforementioned effect is unclear, but is assumed to be as below.

The polymer film according to the present disclosure contains a silsesquioxane polymer. Since the silsesquioxane polymer has a structure in which three oxygen atoms are bonded to a silicon atom, it is considered that the silsesquioxane polymer contributes to the step followability and heat resistance of the polymer film.

On the other hand, JP2021-27307A, JP2020-185795A, and JP2021-054012A do not describe the silsesquioxane polymer.

### —Silsesquioxane Polymer—

The polymer film according to the present disclosure contains a silsesquioxane polymer. In the present disclosure, the silsesquioxane polymer is a polymer having a structure in which one organic group and three oxygen atoms are bonded to one silicon atom, and is a polymer having 13 or more silicon atoms in one molecule.

The skeleton structure of the silsesquioxane polymer is not particularly limited, and may be any of a cage-type structure, a ladder-type structure, or a random structure.

The silsesquioxane polymer preferably includes at least one selected from the group consisting of a partial structure represented by Formula (T1), a partial structure represented by Formula (T2), and a partial structure represented by Formula (T3).

R¹—Si(—OX)₂O_{1/2} (T1)

R¹—Si(—OX)O_{2/2} (T2)

R¹—SiO_{3/2} (T3)

In Formulae (T1) to (T3), R¹'s each independently represent an organic group. X represents a hydrogen atom or an alkyl group having 1 to 6 carbon atoms.

Examples of the alkyl group represented by X include a methyl group, an ethyl group, a n-propyl group, an isopropyl group, and a n-butyl group. The number of carbon atoms in the alkyl group represented by X is preferably 1 to 5, more preferably 1 to 4, and still more preferably 1 to 3.

Examples of the organic group represented by R¹ include a hydrocarbon group. The hydrocarbon group may be a group in which at least one carbon atom in the hydrocarbon group is replaced with a heteroatom (preferably an oxygen atom, a nitrogen atom, or a sulfur atom), a group in which at least one methylene group in the hydrocarbon group is replaced with a carbonyl group, or a combination thereof.

The hydrocarbon group may be an aliphatic hydrocarbon group or an aromatic hydrocarbon group.

The aliphatic hydrocarbon group may be a linear or branched saturated aliphatic hydrocarbon group or a linear or branched unsaturated aliphatic hydrocarbon group.

The aliphatic hydrocarbon group preferably has 1 to 20 carbon atoms, and more preferably has 1 to 15 carbon atoms. Examples of the aliphatic hydrocarbon group include saturated aliphatic hydrocarbon groups such as a methyl group, an ethyl group, an n-propyl group, an isopropyl group, an n-butyl group, an s-butyl group, a t-butyl group, a pentyl group, a hexyl group, an octyl group, a decyl group, a dodecyl group, a tetradecyl group, a hexadecyl group, and an octadecyl group; and unsaturated aliphatic hydrocarbon groups such as an allyl group and a vinyl group.

The aliphatic hydrocarbon group may be an alicyclic hydrocarbon group. In addition, the alicyclic hydrocarbon group may be an alicyclic saturated hydrocarbon group or an alicyclic unsaturated hydrocarbon group. Examples of the alicyclic hydrocarbon group include a cyclopentyl group, a cyclohexyl group, a cycloheptyl group, a cyclopentenyl group, and a cyclohexenyl group.

The aliphatic hydrocarbon group may have a substituent. Examples of the substituent in the aliphatic hydrocarbon group include an aryl group, a hydroxyl group, an amino group, a thiol group, an ester group, an alkoxy group, a halogen atom, and a crosslinkable group described later.

The aromatic hydrocarbon group preferably has 6 to 18 carbon atoms, and more preferably has 6 to 14 carbon atoms. Examples of the aromatic hydrocarbon group include a phenyl group, a naphthyl group, and an anthracenyl group. The aromatic hydrocarbon group may have a substituent. Examples of the substituent in the aromatic hydrocarbon group include an alkyl group, an alkoxy group, an aryl group, a hydroxyl group, an amino group, a thiol group, a halogen atom, and a vinyl group.

Among these, from the viewpoint of improving heat resistance, the silsesquioxane polymer preferably has a crosslinkable group, and the organic group represented by R¹ preferably includes a crosslinkable group.

Examples of the crosslinkable group include a vinyl group, an allyl group, a styryl group, a maleimide group, an epoxy group, and a (meth)acryloyl group. Among these, from the viewpoint of dielectric loss tangent and heat resistance, the crosslinkable group is preferably at least one selected from the group consisting of a vinyl group, an allyl group, a styryl group, and a maleimide group.

In addition, from the viewpoint of heat resistance, the silsesquioxane polymer preferably includes a partial structure represented by Formula (T2) and a partial structure represented by Formula (T3), and a molar ratio of the partial structure represented by Formula (T3) to the partial structure represented by Formula (T2) is preferably 50 or more, more preferably 70 or more, still more preferably 90 or more, and particularly preferably 99 or more. The upper limit value of the above-described molar ratio is not particularly limited.

The molar ratio of the partial structure represented by Formula (T3) to the partial structure represented by Formula (T2) is calculated from the peak surface area ratio of ²⁹Si-NMR.

In addition, from the viewpoint of reducing the dielectric loss tangent and improving the heat resistance, the partial structure represented by Formula (T3) preferably includes a partial structure represented by Formula (T3k) and a partial structure represented by Formula (T3m), and a molar ratio of the partial structure represented by Formula (T3m) to the partial structure represented by Formula (T3k) is preferably 0.01 to 99.

R¹¹—SiO_{3/2} (T2k)

R¹²—SiO₃₂ (T2m)

In Formula (T3k), R¹¹ is an unsubstituted aromatic hydrocarbon group, an aromatic hydrocarbon group having a substituent, or a vinyl group.

In Formula (T3m), R¹² is an aliphatic hydrocarbon group having a C log P value of 2.5 or more.

In the present disclosure, the C log P value is calculated using ChemDraw (registered trademark) Professional (ver. 16.0.1.4) manufactured by PerkinElmer Informatics, Inc.

Specific examples of the aromatic hydrocarbon group represented by R¹¹ are as described above.

In addition, specific examples of the substituent contained in the aromatic hydrocarbon group are as described above.

Specific examples of the aliphatic hydrocarbon group having a C log P value of 2.5 or more, represented by R¹², include those having a C log P value of 2.5 or more among the above-described aliphatic hydrocarbon groups.

Among these, from the viewpoint of heat resistance, R¹² is preferably an unsubstituted aliphatic hydrocarbon group having 4 or more carbon atoms, or an aliphatic hydrocarbon group, which has a substituent, having 4 or more carbon atoms. The number of carbon atoms in R¹² is preferably 4 to 30 and more preferably 6 to 10.

In addition, the molar ratio of the partial structure represented by Formula (T3m) to the partial structure represented by Formula (T3k) is preferably 0.25 to 4, and more preferably 0.33 to 3.

As the aspect 1, it is preferable that R¹¹ is a styryl group and R¹² is an unsubstituted aliphatic hydrocarbon group having 6 or more carbon atoms. In the aspect 1, since the difference in thermal expansion coefficient between the polymer and copper is small, the heat resistance is improved.

As the aspect 2, it is preferable that R¹¹ is a phenyl group and R¹² is an aliphatic hydrocarbon group having 6 or more carbon atoms. In the aspect 2, since the polymer and the copper have excellent adhesiveness, the heat resistance is improved.

In the aspect 2, the storage elastic modulus C at any temperature from 25° C. to 40° C. is preferably 10⁴ Pa to 10⁸ Pa, and the storage elastic modulus D at any temperature from 150° C. to 250° C. is preferably 3×10⁵ Pa or less. In addition, the storage elastic modulus C is more preferably 10⁴ Pa to 10⁸ Pa in a temperature range of 25° C. to 40° C., and the storage elastic modulus D is more preferably 3×10⁵ Pa or less in a temperature range of 150° C. to 250° C.

The storage elastic modulus C and the storage elastic modulus D are measured by the same method as the storage elastic modulus at 160° C. described later. The expression “the storage elastic modulus C at any temperature from 25° C. to 40° C. is 10⁴ Pa to 10⁸ Pa” means that a measured value measured at any temperature from 25° C. to 40° C. falls within a range of 10⁴ Pa to 10⁸ Pa. That is, the temperature at which the storage elastic modulus is 10⁴ Pa to 10⁸ Pa may be present in a range of 25° C. to 40° C., and the temperature at which the storage elastic modulus is less than 10⁴ Pa or more than 10⁸ Pa may be present.

Similarly, the expression “the storage elastic modulus D at any temperature from 150° C. to 250° C. is 3×10⁵ Pa or less” means that the measured value measured at any temperature from 150° C. to 250° C. is within a range of 3×10⁵ Pa or less.

The determination of whether or not the storage elastic modulus C at any temperature from 25° C. to 40° C. is 10⁴ Pa to 10⁸ Pa can be carried out by the following method. For example, in a case where the storage elastic modulus is continuously measured while the temperature is raised at a rate of 5° C./min in a range of 25° C. to 40° C., the determination is made based on whether or not the measured value falls within a range of 10⁴ Pa to 10⁸ Pa. In addition, a method of measuring the storage elastic modulus at a specific temperature (for example, 25° C.) and determining whether or not the storage elastic modulus at the temperature is 10⁴ Pa to 10⁸ Pa may be used.

From the viewpoint of adhesiveness to a metal (particularly, copper), the storage elastic modulus C is more preferably 10⁶ Pa to 10⁸ Pa, and still more preferably 5×10⁶ Pa to 5×10⁷ Pa.

From the viewpoint of adhesiveness to a metal (particularly, copper), the storage elastic modulus D is more preferably 10⁵ Pa or less.

The weight-average molecular weight of the silsesquioxane polymer is preferably 4,000 or more, more preferably 6,000 to 150,000, still more preferably 10,000 to 150,000, and particularly preferably 10,000 to 100,000. In a case where the weight-average molecular weight is 10,000 or more, the heat resistance is more excellent. In addition, in a case where the weight-average molecular weight is 150,000 or less, the step followability is more excellent.

The weight-average molecular weight (Mw) and the number-average molecular weight (Mn) of the silsesquioxane polymer in the present disclosure are molecular weights converted using polystyrene as a standard substance, which are detected by a gel permeation chromatography (GPC) analysis device using a column of TSKgel SuperHM-H (product name, manufactured by Tosoh Corporation) and a solvent tetrahydrofuran, and a differential refractometer.

From the viewpoint of dielectric loss tangent, heat resistance, and step followability, the content of the silsesquioxane polymer is preferably 50% by mass to 100% by mass, and more preferably 60% by mass to 90% by mass with respect to the total mass of the polymer film.

### —Thermoplastic Resin or Thermosetting Resin—

From the viewpoint of dielectric loss tangent and step followability, the polymer film according to the present disclosure preferably further contains a thermoplastic resin or a thermosetting resin other than the silsesquioxane polymer.

The thermoplastic resin may be a thermoplastic elastomer. The elastomer refers to a polymer compound exhibiting elastic deformation. That is, the elastomer corresponds to a polymer compound having a property of being deformed according to an external force in a case where the external force is applied and of being recovered to an original shape in a short time in a case where the external force is removed.

Examples of the thermoplastic resin include a polyurethane resin, a polyester resin, a (meth)acrylic resin, a polystyrene resin, a fluororesin, a polyimide resin, a fluorinated polyimide resin, a polyamide resin, a polyamideimide resin, a polyether imide resin, a cellulose acylate resin, a polyurethane resin, a polyether ether ketone resin, a polycarbonate resin, a polyolefin resin (for example, a polyethylene resin, a polypropylene resin, a resin consisting of a cyclic olefin copolymer, and an alicyclic polyolefin resin), a polyarylate resin, a polyether sulfone resin, a polysulfone resin, a fluorene ring-modified polycarbonate resin, an alicyclic ring-modified polycarbonate resin, and a fluorene ring-modified polyester resin.

The thermoplastic elastomer is not particularly limited, and examples thereof include an elastomer including a constitutional repeating unit derived from styrene (polystyrene-based elastomer), a polyester-based elastomer, a polyolefin-based elastomer, a polyurethane-based elastomer, a polyamide-based elastomer, a polyacryl-based elastomer, a silicone-based elastomer, and a polyimide-based elastomer. The thermoplastic elastomer may be a hydride.

Examples of the polystyrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrides thereof.

Among these, from the viewpoint of dielectric loss tangent, heat resistance, and step followability, the polymer film according to the present disclosure preferably contains a thermoplastic resin containing a constitutional unit derived from a monomer having an aromatic hydrocarbon group, more preferably contains a polystyrene-based elastomer, and more preferably contains a styrene-ethylene-butylene-styrene block copolymer, a styrene-isobutylene-styrene block copolymer, a styrene-ethylene-propylene block copolymer, a styrene-ethylene-propylene-styrene block copolymer, or a styrene-ethylene-ethylene-propylene-styrene copolymer.

Examples of the thermosetting resin include an epoxy resin, an oxazine resin, a bismaleimide resin, a phenol resin, an unsaturated polyester resin, and a silicone resin.

The content of the thermoplastic resin or the thermosetting resin other than the silsesquioxane polymer is not particularly limited, but from the viewpoint of dielectric loss tangent, heat resistance, and step followability, it is preferably 5% by mass to 50% by mass, and more preferably 10% by mass to 40% by mass with respect to the total mass of the polymer film.

### —Filler—

From the viewpoint of dielectric loss tangent, heat resistance, and step followability, the polymer film according to the present disclosure preferably contains a filler.

The filler may be particulate or fibrous, and may be an inorganic filler or an organic filler. From the viewpoint of dielectric loss tangent, heat resistance, and step followability, the polymer film according to the present disclosure preferably contains an inorganic filler.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of the dielectric loss tangent, the heat resistance, and the step followability, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and pulverizing the liquid crystal polymer with a pulverizer or the like to obtain powdery liquid crystal. The liquid crystal polymer particles are preferably smaller than the thickness of each layer.

From the viewpoint of dielectric loss tangent, heat resistance, and step followability, the average particle diameter of the organic filler is preferably 5 nm to 20 μm and more preferably 100 nm to 10 μm.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, as the inorganic filler, from the viewpoint of dielectric loss tangent, heat resistance, and step followability, metal oxide particles or fibers are preferable, silica particles, titania particles, or glass fibers are more preferable, and silica particles or glass fibers are particularly preferable.

The average particle diameter of the inorganic filler is preferably about 20% to about 40% of the thickness of the film, and for example, a filler having an average particle diameter of 25%, 30%, or 35% of the thickness of the film may be selected. In a case where the particles or fibers are flat, the average particle diameter indicates a length in a short side direction.

In addition, from the viewpoint of dielectric loss tangent, heat resistance, and step followability of the polymer film, the average particle diameter of the inorganic filler is preferably 5 nm to 20 μm, more preferably 10 nm to 10 μm, still more preferably 20 nm to 1 am, and particularly preferably 25 nm to 500 nm.

The polymer film according to the present disclosure may contain only one kind of filler or may contain two or more kinds of fillers.

In a case where the polymer film according to the present disclosure contains a filler, from the viewpoint of dielectric loss tangent, heat resistance, and step followability of the polymer film, the content of the filler is preferably 5% by mass to 50% by mass, and more preferably 10% by mass to 40% by mass with respect to the total mass of the polymer film.

In addition, in a case where the silsesquioxane polymer contained in the polymer film according to the present disclosure has a crosslinkable group, the polymer film according to the present disclosure preferably contains a polymerization initiator in order to crosslink the silsesquioxane polymers.

The polymerization initiator is preferably a thermal radical polymerization initiator that generates a radical by heating. Examples of the thermal radical polymerization initiator include azo-based compounds such as 2,2′-azobisisobutyronitrile, 2,2′-azobis(2,4-dimethyl-4-methoxyvaleronitrile), 2,2′-azobis(2,4-dimethylvaleronitrile), dimethyl-2,2′-azobis(2-methylpropionate), 2,2′-azobis(2-methylbutyronitrile), 1,1′-azobis(cyclohexane-1-carbonitrile), 2,2′-azobis(N-butyl-2-methylpropionamide), dimethyl-1,1′-azobis(1-cyclohexanecarboxylate), and 2,2′-azobis[2-(2-imidazolin-2-yl)propane]dihydrochloride; organic peroxides such as 1,1-di(t-hexylperoxy)cyclohexane, 1,1-di(t-butylperoxy)cyclohexane, 2,2-di(4,4-di-(t-butylperoxy)cyclohexyl)propane, t-hexylperoxyisopropyl monocarbonate, t-butylperoxy-3,5,5-trimethylhexanoate, t-butylperoxylaurate, dicumyl peroxide, di-t-butyl peroxide, t-butylperoxy-2-ethylhexanoate, t-hexylperoxy-2-ethylhexanoate, cumene hydroperoxide, and t-butylhydroperoxide; and inorganic peroxides such as potassium persulfate, ammonium persulfate, and hydrogen peroxide.

The content of the polymerization initiator is not particularly limited, but from the viewpoint of curing properties, is preferably 0.1% by mass to 10% by mass, and more preferably 1% by mass to 5% by mass with respect to the total mass of the polymer film.

### —Other Additives—

The polymer film according to the present disclosure may contain other additives in addition to the above-described components.

Known additives can be used as other additives. Specific examples of the other additives include a curing agent, a leveling agent, an antifoaming agent, an antioxidant, an ultraviolet absorbing agent, a flame retardant, and a colorant.

From the viewpoint of heat resistance and step followability, the average thickness of the polymer film according to the present disclosure is preferably 10 μm or more, more preferably 15 μm to 40 μm, and still more preferably 20 μm to 30 μm.

The dielectric loss tangent of the polymer film according to the present disclosure is 0.01 or less, preferably 0.006 or less, more preferably 0.005 or less, and still more preferably 0.003 or less. In addition, the dielectric loss tangent of the polymer film according to the present disclosure is preferably more than 0 and 0.004 or less, and more preferably more than 0 and 0.003 or less.

In the present disclosure, the dielectric loss tangent is measured by the following method.

The dielectric loss tangent is measured by a resonance perturbation method at a frequency of 28 GHz. A 28 GHz cavity resonator (“CP531” manufactured by Kanto Electronic Application & Development Inc.) is connected to a network analyzer (“E8363B” manufactured by Agilent Technologies, Inc.), a measurement sample is inserted into the cavity resonator, and the measurement is performed from the change in resonance frequency before and after the insertion for 96 hours in an environment of a temperature of 25° C. and a humidity of 60% RH.

From the viewpoint of step followability, the storage elastic modulus of the polymer film according to the present disclosure at 160° C. is preferably 0.5 MPa or less and more preferably 0.3 MPa or less. The lower limit value of the storage elastic modulus is not particularly limited, but is preferably 0.01 MPa from the viewpoint of heat resistance. The storage elastic modulus at 160° C. is more preferably 0.05 MPa to 0.5 MPa.

In the present disclosure, the storage elastic modulus of the polymer film at 160° C. is measured by the following method.

Using a rheometer (product name “RS6000”, manufactured by EKO Instruments Co., Ltd.), a storage elastic modulus of the polymer film at 160° C. is measured under the following conditions. The samples are superimposed so that the thickness is about 0.1 mm. The elastic modulus at a point in time of 5 minutes after the start of measurement is read, and the average value of the n=3 measurements is calculated.
Force control mode: (Fn=2N)
Frequency: 1 Hz
Strain: 0.2%
Temperature: constant at 160° C.
Measurement time: 15 minutes

In addition, from the viewpoint of adhesiveness to a metal, the polymer film according to the present disclosure preferably has a storage elastic modulus A at any temperature from 25° C. to 40° C. of 10⁴ Pa to 10⁸ Pa, and preferably has a storage elastic modulus B at any temperature from 150° C. to 250° C. of 10⁶ Pa or less. From the viewpoint of adhesiveness to a metal, the storage elastic modulus A is more preferably 10⁴ Pa to 10⁸ Pa in the entire temperature range of 25° C. to 40° C., and the storage elastic modulus B is still more preferably 10⁶ Pa or less in the entire temperature range of 150° C. to 250° C.

The storage elastic modulus A and the storage elastic modulus B are measured by the same method as the storage elastic modulus at 160° C.

The expression “the storage elastic modulus A at any temperature from 25° C. to 40° C. is 10⁴ Pa to 10⁸ Pa” means that a measured value measured at any temperature from 25° C. to 40° C. falls within a range of 10⁴ Pa to 10⁸ Pa.

Similarly, the expression “the storage elastic modulus B at any temperature from 150° C. to 250° C. is 10⁶ Pa or less” means that the measured value measured at any temperature from 150° C. to 250° C. is within a range of 10⁶ Pa or less.

From the viewpoint of adhesiveness to a metal (particularly, copper), the polymer film according to the present disclosure preferably has a storage elastic modulus A of 10⁶ Pa to 10⁸ Pa, and more preferably has a storage elastic modulus B of 3×10⁵ Pa or less.

From the viewpoint of adhesiveness to a metal (particularly, copper), the polymer film according to the present disclosure still more preferably has a storage elastic modulus A of 5×10⁶ Pa to 5×10⁷ Pa, and still more preferably has a storage elastic modulus B of 10⁵ Pa or less.

The polymer film according to the present disclosure is preferably a bonding sheet. The bonding sheet is a sheet that is used by being attached to another substrate, and has an adhesion function.

### [Laminate]

The laminate according to the present disclosure includes a layer A, and a layer B disposed on at least one surface of the layer A, in which the laminate contains a silsesquioxane polymer, and has a dielectric loss tangent of 0.01 or less.

In addition, the laminate according to the present disclosure includes the layer A, and the layer B disposed on at least one surface of the layer A, in which the layer B may be the polymer film according to the present disclosure.

The laminate according to the present disclosure contains a silsesquioxane polymer, so that the layer B functions as a step following layer, and the laminate has excellent step followability. In addition, the silsesquioxane polymer has a structure in which three oxygen atoms are bonded to a silicon atom, and it is considered to contribute to the heat resistance of the laminate.

On the other hand, JP2021-27307A, JP2020-185795A, and JP2021-054012A do not describe the silsesquioxane polymer.

### <Layer A>

The laminate according to the present disclosure has a layer A in which a layer B described later is provided. From the viewpoint of setting the dielectric loss tangent of the laminate to 0.01 or less, the layer A preferably contains a polymer having a dielectric loss tangent of 0.01 or less.

The layer A may contain only one kind of polymer having a dielectric loss tangent of 0.01 or less, or may contain two or more kinds thereof.

From the viewpoint of the dielectric loss tangent of the laminate, the dielectric loss tangent of the polymer having a dielectric loss tangent of 0.01 or less is preferably 0.006 or less and more preferably more than 0 and 0.004 or less.

Examples of the polymer having a dielectric loss tangent of 0.01 or less include thermoplastic resins such as a liquid crystal polymer, a fluororesin, a polymerized substance of a compound which has a cyclic aliphatic hydrocarbon group and a group having an ethylenically unsaturated bond, polyether ether ketone, polyolefin, polyamide, polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide, and a cyanate resin.

### —Liquid Crystal Polymer—

From the viewpoint of dielectric loss tangent of the laminate, the polymer having a dielectric loss tangent of 0.01 or less is preferably a liquid crystal polymer. That is, the layer A preferably contains a liquid crystal polymer.

The kind of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) a liquid crystal polymer obtained by polycondensing a plurality of kinds of aromatic hydroxycarboxylic acids.
3) a liquid crystal polymer obtained by polycondensing (i) an aromatic dicarboxylic acid and (ii) at least one compound selected from the group consisting of an aromatic diol, an aromatic hydroxyamine, and an aromatic diamine.
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

A melting point of the liquid crystal polymer is preferably equal to or higher than 250° C., more preferably 250° C. to 350° C., and still more preferably 260° C. to 330° C.

In the present disclosure, the melting point is measured using a differential scanning calorimetry apparatus. For example, the measurement is performed using product name “DSC-60A Plus” (manufactured by Shimadzu Corporation). A temperature rising rate in the measurement is set to 10° C./minute.

The weight-average molecular weight of the liquid crystal polymer is preferably equal to or less than 1,000,000, more preferably 3,000 to 300,000, still more preferably 5,000 to 100,000, and particularly preferably 5,000 to 30,000.

The liquid crystal polymer preferably contains an aromatic polyester amide from a viewpoint of further decreasing the dielectric loss tangent. The aromatic polyester amide is a resin having at least one aromatic ring and having an ester bond and an amide bond. Among these, from the viewpoint of heat resistance, the aromatic polyester amide is preferably a fully aromatic polyester amide.

The aromatic polyester amide is preferably a crystalline polymer. The layer A preferably contains a crystalline aromatic polyester amide. In a case where the aromatic polyester amide contained in the layer A is crystalline, the dielectric loss tangent is further reduced.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature rising rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a constitutional unit represented by Formula 1, a constitutional unit represented by Formula 2, and a constitutional unit represented by Formula 3.

—O—Ar¹—CO— Formula 1

—CO—Ar²—CO— Formula 2

—NH—Ar³—O— Formula 3

In Formula 1 to Formula 3, Ar¹, Ar², and Ar³ each independently represent a phenylene group, a naphthylene group, or a biphenylylene group.

Hereinafter, the constitutional unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar¹ is preferably a p-phenylene group, a 2,6-naphthylene group, or a 4,4′-biphenylylene group, and more preferably a 2,6-naphthylene group.

In a case where Ar¹ is a p-phenylene group, the unit 1 is, for example, a constitutional unit derived from p-hydroxybenzoic acid.

In a case where Ar¹ is a 2,6-naphthylene group, the unit 1 is, for example, a constitutional unit derived from 6-hydroxy-2-naphthoic acid.

In a case where Ar¹ is a 4,4′-biphenylylene group, the unit 1 is, for example, a constitutional unit derived from 4′-hydroxy-4-biphenylcarboxylic acid.

In Formula 2, Ar² is preferably a p-phenylene group, an m-phenylene group, or a 2,6-naphthylene group, and more preferably an m-phenylene group.

In a case where Ar² is a p-phenylene group, the unit 2 is, for example, a constitutional unit derived from terephthalic acid.

In a case where Ar² is an m-phenylene group, the unit 2 is, for example, a constitutional unit derived from isophthalic acid.

In a case where Ar² is a 2,6-naphthylene group, the unit 2 is, for example, a constitutional unit derived from 2,6-naphthalenedicarboxylic acid.

In Formula 3, Ar³ is preferably a p-phenylene group or a 4,4′-biphenylylene group, and more preferably a p-phenylene group.

In a case where Ar³ is a p-phenylene group, the unit 3 is, for example, a constitutional unit derived from p-aminophenol.

In a case where Ar³ is a 4,4′-biphenylylene group, the unit 3 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

In a case where a ratio of the content of the unit 2 to the content of the unit 3 is expressed as [Content of unit 2]/[Content of unit 3](mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other constitutional units other than the unit 1 to the unit 3. A content of other constitutional units is preferably 10% by mole or less and more preferably 5% by mole or less with respect to the total content of all constitutional units.

Aromatic polyester amide is preferably produced by subjecting a source monomer corresponding to the constitutional unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

### —Fluororesin—

From the viewpoint of heat resistance and mechanical strength, the polymer having a dielectric loss tangent of 0.01 or less may be a fluororesin.

In the present disclosure, the kind of the fluororesin is not particularly limited, and a known fluororesin can be used.

Examples of the fluororesin include a homopolymer and a copolymer containing a constitutional unit derived from a fluorinated α-olefin monomer, that is, an α-olefin monomer containing at least one fluorine atom. In addition, examples of the fluororesin include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated α-olefin monomer include CF₂═CF₂, CHF═CF₂, CH₂═CF₂, CHCl═CHF, CClF═CF₂, CCl₂═CF₂, CClF═CClF, CHF═CCl₂, CH₂═CClF, CCl₂═CClF, CF₃CF═CF₂, CF₃CF═CHF, CF₃CH═CF₂, CF₃CH═CH₂, CHF₂CH═CHF, CF₃CF═CF₂, and perfluoro(alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a constitutional unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by Formula: H₂C═CR′COO—(CH₂)ₙ—R—(CH₂)ₙ—OOCR′═CH₂.

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

—Polymerized Substance of Compound which has Cyclic Aliphatic Hydrocarbon Group and Group Having Ethylenically Unsaturated Bond—

The polymer having a dielectric loss tangent of 0.01 or less may be a polymerized substance of a compound which has a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### —Polyphenylene Ether—

The polymer having a dielectric loss tangent of 0.01 or less may be a polyphenylene ether.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

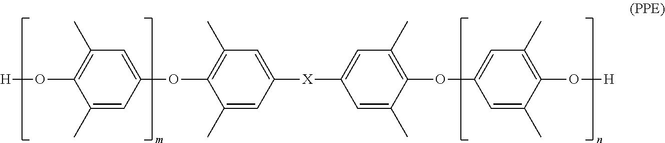

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and preferably 500 to 3,000. In addition, in a case where the heat curing is not performed, the weight-average molecular weight (Mw) of the polyphenylene ether is not particularly limited, but is preferably 3,000 to 100,000 and preferably 5,000 to 50,000.

### —Aromatic Polyether Ketone—

The polymer having a dielectric loss tangent of 0.01 or less may be an aromatic polyether ketone.

The aromatic polyether ketone is not particularly limited, and a known aromatic polyether ketone can be used.

The aromatic polyether ketone is preferably a polyether ether ketone.

The polyether ether ketone is one kind of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

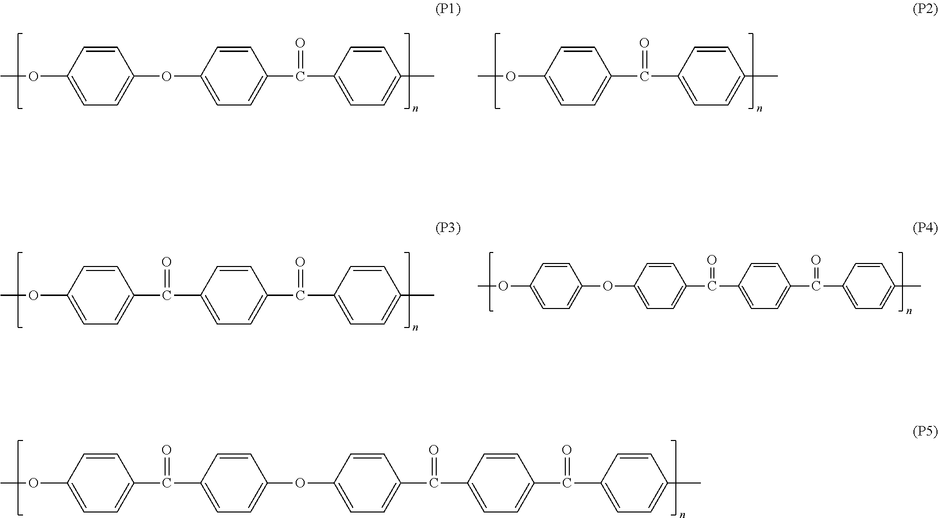

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

From the viewpoint of dielectric loss tangent of the laminate, the content of the polymer having a dielectric loss tangent of 0.01 or less is preferably 10% by mass or more, more preferably 20% by mass or more, and particularly preferably 20% by mass to 100% by mass with respect to the total mass of the layer A.

In a case where the polymer having a dielectric loss tangent of 0.01 or less is a liquid crystal polymer, from the viewpoint of dielectric loss tangent of the laminate, the content of the polymer is preferably 10% by mass or more, more preferably 20% by mass or more, and particularly preferably 20% by mass to 50% by mass with respect to the total mass of the layer A.

The layer A may contain a filler in addition to the polymer having a dielectric loss tangent of 0.01 or less.

### —Filler—

The filler may be particulate or fibrous, and may be an inorganic filler or an organic filler. Specific examples of the inorganic filler and the organic filler are as described above.

Among these, from the viewpoint of dielectric loss tangent, heat resistance, and step followability of the laminate, the filler contained in the layer A is preferably an organic filler and more preferably liquid crystal polymer particles.

The layer A may contain only one or two or more kinds of the fillers.

In a case where the layer A contains a filler, from the viewpoint of the dielectric loss tangent, the heat resistance, and the step followability of the laminate, the content of the filler is preferably 30% by mass to 95% by mass, more preferably 50% by mass to 90% by mass, and particularly preferably 60% by mass to 80% by mass with respect to the total mass of the layer A.

### —Other Additives—

The layer A may contain an additive other than the above-described components.

The preferred aspect of the other additives which may be included in the layer A is the same as the preferred aspect of the other additives which may be included in the polymer film according to the present disclosure.

In addition, the layer A may contain, as other additives, a resin other than the polymer having a dielectric loss tangent of 0.01 or less.

Examples of the resin other than the polymer having a dielectric loss tangent of 0.01 or less include thermoplastic resins other than liquid crystal polyester, such as polypropylene, polyamide, polyester other than liquid crystal polyester, polyphenylene sulfide, polyether ketone, polycarbonate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

The total content of the other additives in the layer A is preferably 25 parts by mass or less, more preferably 10 parts by mass or less, and still more preferably 5 parts by mass or less with respect to 100 parts by mass of the content of the polymer having a dielectric loss tangent of 0.01 or less.

The average thickness of the layer A is not particularly limited, but from the viewpoint of dielectric loss tangent, heat resistance, and step followability of the laminate, the average thickness is preferably 5 μm to 90 μm, more preferably 10 μm to 70 μm, and particularly preferably 15 μm to 50 μm.

A measuring method of the average thickness of each layer in the laminate according to the present disclosure is as follows.

The laminate is cut along a plane perpendicular to the in-plane direction of the laminate, the thickness is measured at five or more points in the cross section, and the average value thereof is defined as the average thickness.

From the viewpoint of setting the dielectric loss tangent of the laminate to 0.01 or less, the dielectric loss tangent of the layer A is preferably 0.01 or less, more preferably 0.005 or less, and still more preferably more than 0 and 0.003 or less.

### <Layer B>

The laminate according to the present disclosure includes the layer B on at least one surface of the layer A. The layer B is preferably a surface layer (outermost layer).

The layer B contains a silsesquioxane polymer. The preferred aspect of the silsesquioxane polymer contained in the layer B is the same as the preferred aspect of the silsesquioxane polymer contained in the polymer film according to the present disclosure.

From the viewpoint of dielectric loss tangent of the laminate and step followability, the layer B preferably further contains a thermoplastic resin or a thermosetting resin other than the silsesquioxane polymer. The preferred aspects of the thermoplastic resin and the thermosetting resin which may be contained in the layer B are the same as the preferred aspects of the thermoplastic resin and the thermosetting resin which may be contained in the polymer film according to the present disclosure.

From the viewpoint of dielectric loss tangent, heat resistance, and step followability of the laminate, it is more preferable that the layer B contains a filler.

The preferred aspect of the filler which may be contained in the layer B is the same as the preferred aspect of the filler which may be contained in the polymer film according to the present disclosure.

In addition, in a case where the silsesquioxane polymer contained in the layer B has a crosslinkable group, the layer B preferably contains a polymerization initiator in order to crosslink the silsesquioxane polymers. The preferred aspect of the polymerization initiator which may be contained in the layer B is the same as the preferred aspect of the polymerization initiator which may be contained in the polymer film according to the present disclosure.

The layer B may contain an additive other than those described above.

The preferred aspect of the other additives which may be included in the layer B is the same as the preferred aspect of the other additives which may be included in the polymer film according to the present disclosure.

The layer B is preferably a surface layer (outermost layer). The layer B has excellent step followability, and thus has excellent adhesiveness in the bonding to the metal wire.

From the viewpoint of heat resistance and step followability, the average thickness of the layer B is preferably 10 μm or more, more preferably 15 μm to 40 μm, and still more preferably m to 30 μm.

From the viewpoint of setting the dielectric loss tangent of the laminate to 0.01 or less, the dielectric loss tangent of the layer B is preferably 0.01 or less, more preferably 0.006 or less, and still more preferably more than 0 and 0.004 or less.

From the viewpoint of step followability, the elastic modulus of the layer B at 160° C. is preferably 0.5 MPa or less and more preferably 0.3 MPa or less. The lower limit value of the elastic modulus is not particularly limited, but is preferably 0.01 MPa from the viewpoint of heat resistance.

In the present disclosure, the elastic modulus of the layer B at 160° C. is measured by the following method.

First, the laminate is cut in a cross section with a microtome or the like, and the layer B is specified from the image observed with an optical microscope. Next, the elastic modulus of the specified layer B is measured as an indentation elastic modulus using a nanoindentation method. The indentation elastic modulus is measured by using a microhardness meter (product name “DUH-W201”, manufactured by Shimadzu Corporation) to apply a load at a loading rate of 0.28 mN/see with a Vickers indenter at 160° C., holding a maximum load of 10 mN for 10 seconds, and then unloading at a loading rate of 0.28 mN/sec.

From the viewpoint of heat resistance and step followability, the laminate according to the present disclosure preferably further has a layer C in addition to the layer A and the layer B, and more preferably has the layer B, the layer A, and the layer C in this order.

### <Layer C>

The layer C is preferably an adhesive layer. That is, the layer C is preferably a surface layer (outermost layer).

From the viewpoint of dielectric loss tangent of the laminate, the layer C preferably contains at least one polymer.

The preferred aspect of the polymer used in the layer C is the same as the preferred aspect of the polymer having a dielectric loss tangent of 0.01 or less, which is used in the layer A.

The polymer contained in the layer C may be the same as or different from the polymer contained in the layer A or the layer B, but from the viewpoint of adhesiveness between the layer A and the layer C, it is preferable that the polymer contained in the layer C is the same as the polymer contained in the layer A.

In addition, since the layer C is used to adhere the metal layer and the layer A, it is preferable that the layer C contains an epoxy resin.

The epoxy resin is preferably a crosslinked product of a polyfunctional epoxy compound. The polyfunctional epoxy compound refers to a compound having two or more epoxy groups. The number of epoxy groups in the polyfunctional epoxy compound is preferably 2 to 4.

In particular, from the viewpoint of dielectric loss tangent of the laminate and adhesiveness with the metal layer, the layer C preferably contains aromatic polyester amide and an epoxy resin.

The layer C may contain a filler.

Preferred aspects of the filler which is used in the layer C are the same as the preferred aspects of the filler which is used in the layer A.

The layer C may contain an additive other than the additives described above.

Preferred aspects of other additives which are used in the layer C are the same as the preferred aspects of other additives which are used in the layer A, except as described below.

From the viewpoint of dielectric loss tangent of the laminate and adhesiveness with the metal, it is preferable that the average thickness of the layer C is smaller than the average thickness of the layer A.

From the viewpoint of dielectric loss tangent of the laminate and adhesiveness with the metal layer, a value of T^{A}/T^{C}, which is a ratio of an average thickness T^{A} of the layer A to an average thickness T^{C} of the layer C, is preferably more than 1, more preferably 2 to 100, still more preferably 2.5 to 20, and particularly preferably 3 to 10.

From the viewpoint of dielectric loss tangent of the laminate and adhesiveness to the metal layer, a value of T^{B}/T^{C}, which is a ratio of the average thickness T^{B} of the layer B to the average thickness T^{C} of the layer C, is preferably more than 1, more preferably 2 to 100, still more preferably 2.5 to 20, and particularly preferably 3 to 10.

Furthermore, from the viewpoint of dielectric loss tangent of the film and adhesiveness to the metal layer, the average thickness of the layer C is preferably 0.1 μm to 20 μm, more preferably 0.5 μm to 15 μm, still more preferably 1 μm to 10 μm, and particularly preferably 2 m to 8 μm.

From the viewpoint of strength and electrical characteristics (characteristic impedance) in a case of being laminated with the metal layer, an average thickness of the laminate according to the present disclosure is preferably 6 μm to 200 μm, more preferably 12 am to 100 μm, and particularly preferably 20 μm to 80 μm.

The average thickness of the laminate is measured at optional five sites using an adhesive film thickness meter, for example, an electronic micrometer (product name, “KG3001A”, manufactured by Anritsu Corporation), and the average value of the measured values is defined as the average thickness of the film.

### <Physical Properties of Laminate>

In the laminate according to the present disclosure, the dielectric loss tangent is preferably 0.01 or less, more preferably 0.006 or less, and still more preferably more than 0 and 0.004 or less.

### <Production Method of Laminate>

### (Film Formation)

The production method of a laminate according to the present disclosure is not particularly limited, and a known method can be referred to.

Suitable examples of the film forming method include a co-casting method, a multilayer coating method, and a co-extrusion method. Among these, the film forming method is preferably a co-casting method.

In a case where the multilayer structure in the laminate is produced by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and 7-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as 7-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in a case where the laminate is produced by a production method such as the co-casting method, the multilayer coating method, the co-extrusion method, or the like described above, a support may be used in the production method of the laminate according to the present disclosure.

Examples of the support include a metal drum, a metal band, a glass plate, a resin film, and a metal foil. Among these, the support is preferably a metal drum, a metal band, or a resin film.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

An average thickness of the support is not particularly limited, but is preferably 25 μm or more and 75 μm or less and more preferably 50 μm or more and 75 μm or less.

In addition, a method for removing at least a part of the solvent from a cast or applied film-like composition (a coating film) is not particularly limited, and a known drying method can be used.

### (Stretching)

In the laminate according to the present disclosure, stretching can be combined as appropriate from the viewpoint of controlling molecular alignment and adjusting thermal expansion coefficiency and mechanical properties. The stretching method is not particularly limited, and a known method can be referred to, and the stretching method may be carried out in a solvent-containing state or in a dry film state. The stretching in the solvent-containing state may be carried out by gripping and stretching the laminate, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

### <Applications>

The laminate according to the present disclosure can be used for various applications. Among the various applications, the film can be used suitably as a film for an electronic component such as a printed wiring board and more suitably for a flexible printed circuit board.

In addition, the laminate according to the present disclosure can be suitably used as a liquid crystal polymer film for metal adhesion.

### [Wiring Board]

A wiring board according to the present disclosure comprises a substrate, a wiring pattern disposed on at least one surface of the substrate, a layer B disposed between the wiring patterns and on the wiring pattern, and a layer A disposed on the layer B, in which the layer B contains a silsesquioxane polymer, and the wiring board has a dielectric loss tangent of 0.01 or less.

In addition, the wiring board according to the present disclosure may comprise a substrate, a wiring pattern disposed on at least one surface of the substrate, a layer B disposed between the wiring patterns and on the wiring pattern, and a layer A disposed on the layer B, in which the layer B may be the polymer film according to the present disclosure.

Since the wiring board according to the present disclosure contains a silsesquioxane polymer, the gap around the wiring pattern is reduced, and the heat resistance is excellent.

### <Substrate>

The material of the substrate is not particularly limited, but it is preferable that the substrate contains a resin, it is preferable that the substrate contains a liquid crystal polymer, and it is more preferable that the substrate is a liquid crystal polymer film.

The average thickness of the substrate is not particularly limited, but is preferably 5 μm to 100 μm, more preferably 10 μm to 80 μm, and still more preferably 20 μm to 70 μm.

### <Wiring Pattern>

The wiring board according to the present disclosure has a wiring pattern on at least one surface of the substrate. Since the layer B is disposed between the wiring patterns and on the wiring pattern, in the wiring board according to the present disclosure, the wiring pattern is embedded. The wiring pattern can be embedded in the wiring board, for example, by the following method. First, a metal layer is formed on a substrate, and the metal layer is etched in a patterned manner. In this manner, a substrate with a wiring pattern is obtained. Next, the substrate with a wiring pattern and another substrate having the layer A and the layer B are overlaid such that the wiring pattern in the substrate with a wiring pattern and the layer B are in contact with each other. The substrate with a wiring pattern and the other substrate may be bonded to each other by bonding or thermal welding after being laminated. In this manner, a wiring board in which the wiring pattern is embedded is obtained.

A material of the wiring pattern is not particularly limited, but is preferably a metal and more preferably silver or copper.

A thickness of the wiring pattern is not particularly limited, but is preferably 5 μm to 40 μm and more preferably 5 μm to 35 μm.

The thickness of the wiring pattern is measured by cutting the wiring board with a microtome and observing the wiring board with an optical microscope.

### <Layer B>

The wiring board according to the present disclosure has a layer B between the wiring patterns and on the wiring pattern. The layer B contains a silsesquioxane polymer.

In the production process of the wiring board according to the present disclosure, it is preferable to perform a heating treatment, and the silsesquioxane polymer contained in the layer B of the wiring board according to the present disclosure is preferably obtained by thermally curing the silsesquioxane polymer used as a raw material. That is, in a case where a silsesquioxane polymer having a crosslinkable group is used as a raw material, the layer B preferably contains a silsesquioxane polymer having a crosslinked structure in which molecules are crosslinked with each other.

The silsesquioxane polymer preferably includes at least one selected from the group consisting of a partial structure represented by Formula (T1a), a partial structure represented by Formula (T2a), and a partial structure represented by Formula (T3a).

R²—Si(—OX)₂O_{1/2} (T1a)

R²—Si(—OX)O_{2/2} (T2a)

R²—SiO_{3/2} (T3a)

In Formulae (T1a) to (T3a), R²'s each independently represent an organic group, and the R²'s may be linked to each other. X represents a hydrogen atom or an alkyl group having 1 to 6 carbon atoms.

In a case where the respective R²'s are not linked to each other, examples of R² include the same ones as R¹ in Formulae (T1) to (T3).

In a case where the respective R²'s are linked to each other, it is preferable that R² includes a structure derived from at least one crosslinkable group selected from the group consisting of a vinyl group, an allyl group, a styryl group, and a maleimide group. Specifically, the structure derived from a crosslinkable group means a structure obtained by polymerization of a crosslinkable group.

In addition, from the viewpoint of heat resistance, the silsesquioxane polymer preferably includes a partial structure represented by Formula (T2a) and a partial structure represented by Formula (T3a), and a molar ratio of the partial structure represented by Formula (T3a) to the partial structure represented by Formula (T2a) is preferably 50 or more and more preferably 70 or more. The upper limit value of the above-described molar ratio is not particularly limited.

The molar ratio of the partial structure represented by Formula (T3a) to the partial structure represented by Formula (T2a) is calculated from the peak surface area ratio of ²⁹Si-NMR.

From the viewpoint of dielectric loss tangent and heat resistance, the content of the silsesquioxane polymer is preferably 50% by mass to 100% by mass, and more preferably 60% by mass to 90% by mass with respect to the total mass of the layer B.

From the viewpoint of dielectric loss tangent and step followability, it is preferable that the layer B further contains a thermoplastic resin or a thermosetting resin other than the silsesquioxane polymer. Preferred aspects of the thermoplastic resin and the thermosetting resin which may be included in the layer B in the wiring board according to the present disclosure are the same as the preferred aspects of the thermoplastic resin and the thermosetting resin which may be included in the polymer film according to the present disclosure.

From the viewpoint of dielectric loss tangent and heat resistance, the layer B more preferably contains a filler.

The preferred aspect of the filler which may be contained in the layer B is the same as the preferred aspect of the filler which may be contained in the layer B of the laminate according to the present disclosure.

The layer B may contain an additive other than those described above.

The preferred aspect of the other additives which may be included in the layer B is the same as the preferred aspect of the other additives which may be included in the polymer film according to the present disclosure.

In the layer B, a thickness of the thickest portion is preferably 10 μm or more, more preferably 15 μm to 40 μm, and still more preferably 20 μm to 30 μm. The thickest portion here means a portion in which the wiring pattern is not embedded.

### <Layer A>

The wiring board according to the present disclosure has a layer A in which the layer B is provided. The preferred aspect of the layer A is the same as the preferred aspect of the layer A included in the laminate according to the present disclosure.

From the viewpoint of heat resistance, it is preferable that the wiring board according to the present disclosure further includes a layer C in addition to the layer A and the layer B, and the layer C is disposed on the layer A. The preferred aspect of the layer C is the same as the preferred aspect of the layer C which may be included in the laminate according to the present disclosure.

### <Production Method of Wiring Board>

### (First Aspect)

It is preferable that the first aspect in the production method of a wiring board according to the present disclosure includes a step of superimposing the laminate according to the present disclosure on a wiring pattern of the substrate with a wiring pattern, and a step of heating the substrate with a wiring pattern and the laminate according to the present disclosure in a state of being superimposed on each other to obtain a wiring board. The substrate with a wiring pattern and the laminate are superimposed such that the wiring pattern of the substrate with a wiring pattern and the layer B in the laminate are in contact with each other.

### —Superimposing Step—

In the first aspect of the production method of a wiring board according to the present disclosure, the laminate according to the present disclosure is superimposed on the wiring pattern of the substrate with a wiring pattern.

In a case where the laminates are superimposed, the laminate may be simply placed on the wiring pattern, or the laminate may be pressed against the wiring pattern while applying pressure.

In the substrate with a wiring pattern, the wiring pattern may be formed only on one surface of the substrate or the wiring pattern may be formed on both surfaces of the substrate.

The substrate with a wiring pattern can be produced using a known method. For example, a metal layer is adhered to at least one surface of the substrate to obtain a wiring board comprising the substrate and the metal layer disposed on at least one surface of the substrate. A known pattering treatment is performed on the metal layer, whereby the substrate with a wiring pattern is obtained.

A preferred aspect of the substrate and the wiring pattern in the substrate with a wiring pattern is the same as the preferred aspect of the substrate and the wiring pattern described in the section of the wiring board.

### —Heating Step—

In the first aspect of the production method of a wiring board of the present disclosure, after the above-described superimposing step, the substrate with a wiring pattern and the laminate according to the present disclosure are heated in a state of being superimposed with each other to obtain a wiring board.

A heating method is not particularly limited, and the heating can be performed, for example, using a heat pressing machine.

The heating temperature is preferably 50° C. to 300° C. and more preferably 100° C. to 250° C.

In a case of heating, it is preferable to pressurize. The pressure is preferably 0.5 MPa to 30 MPa and more preferably 1 MPa to 20 MPa.

The heating time is not particularly limited, and is, for example, 1 minute to 2 hours.

### (Second Aspect)

A second aspect of the production method of a wiring board according to the present disclosure preferably includes a step of coating a support with a solution for forming a layer A to form the layer A, a step of superimposing the polymer film according to the present disclosure and the substrate with a wiring pattern in this order on the layer A, and a step of heating the support on which the layer A is formed, the polymer film according to the present disclosure, and the substrate with a wiring pattern in a superimposed state to obtain a wiring board. The polymer film and the substrate with a wiring pattern are superimposed such that the wiring pattern of the substrate with a wiring pattern and the polymer film are in contact with each other.

Examples of the support include the same support as the support used in the above-described production method of a laminate.

The details of the substrate with a wiring pattern are the same as those in the first aspect.

The details of the heating step are the same as those in the first aspect.

### <Applications>

The wiring board according to the present disclosure can be used for various applications. In particular, the wiring board according to the present disclosure can be suitably used for a flexible printed circuit board.

### [Silsesquioxane Polymer]

The preferred aspect of the silsesquioxane polymer according to the present disclosure is the same as the preferred aspect of the silsesquioxane polymer contained in the polymer film according to the present disclosure.

The silsesquioxane polymer according to the present disclosure has a dielectric loss tangent of 0.01 or less, preferably 0.006 or less, more preferably 0.005 or less, still more preferably 0.003 or less, and particularly preferably 0.0025 or less. In addition, the dielectric loss tangent of the silsesquioxane polymer according to the present disclosure is preferably more than 0 and 0.01 or less.

### [Polymer Composition]

The polymer composition according to the present disclosure contains the silsesquioxane polymer according to the present disclosure.

Preferred aspects of the silsesquioxane polymer contained in the polymer composition according to the present disclosure are the same as the preferred aspects of the silsesquioxane polymer contained in the polymer film according to the present disclosure.

It is preferable that the polymer composition according to the present disclosure further contains a thermoplastic resin or a thermosetting resin other than the silsesquioxane polymer.

The preferred aspect of the thermoplastic resin or the thermosetting resin which may be contained in the polymer composition according to the present disclosure is the same as the preferred aspect of the thermoplastic resin or the thermosetting resin which may be contained in the polymer film according to the present disclosure.

It is preferable that the polymer composition according to the present disclosure further contains an inorganic filler.

The preferred aspect of the inorganic filler which may be contained in the polymer composition according to the present disclosure is the same as the preferred aspect of the inorganic filler which may be contained in the polymer film according to the present disclosure.

### EXAMPLES

Hereinafter, the present disclosure will be described in more detail with reference to Examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

Details of each material used for preparing a single-sided copper-clad multilayer film (laminate) and a bonding sheet (polymer film) are as follows.

### <<Material of Layer a in Single-Sided Copper-Clad Multilayer Film>>

### <Polymer>

P1: Aromatic polyester amide prepared by the following preparation method
P6: polyphenylene ether resin (product name “S202A”, manufactured by Asahi Kasei Corporation)

### —Synthesis of Aromatic Polyester Amide P1—

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature increases from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off by-produced acetic acid and unreacted acetic anhydride, and maintained at 300° C. for 30 minutes. Thereafter, a content is taken out from the reactor and is cooled to the room temperature. The obtained solid was pulverized by a pulverizer to obtain a powdered aromatic polyester amide A1a. A flow start temperature of the aromatic polyester amide A1a was 193° C. In addition, the aromatic polyester amide A1a was a fully aromatic polyester amide.

The aromatic polyester amide A1a was subjected to solid phase polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amide A1b. A flow start temperature of the aromatic polyester amide A1b was 220° C. Aromatic polyester amide A1b is subjected to solid phase polymerization by increasing the temperature from the room temperature to 180° C. for one hour and 25 minutes, next increasing the temperature from 180° C. to 255° C. over six hours and 40 minutes, and maintaining the temperature at 255° C. for five hours in a nitrogen atmosphere, and then, is cooled, and powdered aromatic polyester amide P1 is obtained.

A flow start temperature of the aromatic polyester amide P1 was 302° C. A melting point of aromatic polyester amide P1 was measured using a differential scanning calorimetry apparatus, and the result was 311° C. The dielectric loss tangent of the aromatic polyester amide P1 was 0.003. Solubility of aromatic polyester amide P1 with respect to N-methylpyrrolidone at 140° C. is equal to or greater than 1% by mass.

### <Filler>

PP-1: Liquid crystal polymer particles prepared by preparation method described below
PP-2: Liquid crystal polymer particles prepared by preparation method described below

### —Synthesis of Liquid Crystal Polymer Particles PP-1—

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst were put in a reactor including a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. A temperature increases from a room temperature to 150° C. over 15 minutes while stirring under a nitrogen gas flow, and refluxing is performed at 150° C. for two hours.

Next, the temperature was raised from 150° C. to 310° C. over 5 hours while distilling off by-produced acetic acid and unreacted acetic anhydride, and a polymerized substance was cooled to room temperature. An obtained polymerized substance increases in temperature from the room temperature to 295° C. over 14 hours, and is subjected to solid phase polymerization at 295° C. for one hour. After the solid phase polymerization, the temperature was lowered to room temperature over 5 hours, thereby obtaining liquid crystal polymer particles PP-1. The liquid crystal polymer particles PP-1 had a median diameter (D50) of 7 μm, a dielectric loss tangent of 0.0007, and a melting point of 334° C.

### —Synthesis of Liquid Crystal Polymer Particles PP-2—

Spherical liquid crystal polymer particles were prepared with reference to Production Example 1 described in WO2019/240153A. The liquid crystal polymer particles PP-2 had a median diameter (D50) of 10 μm, a dielectric loss tangent of 0.0021, and a melting point of 325° C.

### <<Materials of Layer B and Bonding Sheet in Multilayer Film>>

### <Silsesquioxane Polymer>

Methyltrimethoxysilane (0.3 mol) and 75.0 g of methyl isobutyl ketone were mixed in a 300 mL three-neck flask, and the mixture was stirred while being heated at an external temperature of 80° C. 18.0 g of a 0.1% by mass potassium hydroxide aqueous solution was added dropwise thereto at a constant speed for 5 minutes, and the mixture was stirred while being heated for 5 hours. During the heating, the reaction was carried out while removing methanol refluxed using a Dean-Stark apparatus to the outside of the system. After the stirring was stopped and the mixture was cooled to room temperature (25° C.) in a water bath, 150 g of methyl isobutyl ketone and 150 g of 5% by mass saline were added thereto to extract an organic phase. The organic phase was washed once with 150 g of a 5% by mass saline solution, twice with 150 g of pure water, and then dried with 45 g of magnesium sulfate, and concentrated under reduced pressure of 35 mmHg at 50° C. to obtain a methyl isobutyl ketone solution of a silsesquioxane polymer SQL.

The silsesquioxane polymers SQ2 to SQ8 were synthesized by changing the methyltrimethoxysilane used for the synthesis of the silsesquioxane polymer SQ1 to the following raw materials, respectively.

For the silsesquioxane polymers SQ9 to SQ16, 0.3 mol of the methyltrimethoxysilane used for the synthesis of the silsesquioxane polymer SQ1 was changed to each of the following two raw materials and adjusted to the following amount used for synthesis.
Raw material of SQ2: phenyltrimethoxysilane
Raw material of SQ3: vinyltrimethoxysilane
Raw material of SQ4: allyltrimethoxysilane
Raw material of SQ5: styryltrimethoxysilane
Raw material of SQ6: N-[3-(trimethoxysilyl)propyl]maleimide
Raw material of SQ7: [2-(3,4-epoxycyclohexyl)ethyl]trimethoxysilane
Raw material of SQ8: 3-(trimethoxysilyl)propyl methacrylate
Raw materials of SQ9: styryltrimethoxysilane (0.15 mol)/decyltrimethoxysilane (0.15 mol)
Raw materials of SQ10: styryltrimethoxysilane (0.075 mol)/decyltrimethoxysilane (0.225 mol)
Raw materials of SQ11: styryltrimethoxysilane (0.15 mol)/hexyltrimethoxysilane (0.15 mol)
Raw materials of SQ12: vinyltrimethoxysilane (0.15 mol)/decyltrimethoxysilane (0.15 mol)
Raw materials of SQ13: phenyltrimethoxysilane (0.15 mol)/hexyltrimethoxysilane (0.15 mol)
Raw materials of SQ14: phenyltrimethoxysilane (0.15 mol)/octyltrimethoxysilane (0.15 mol)
Raw materials of SQ15: phenyltrimethoxysilane (0.12 mol)/hexyltrimethoxysilane (0.18 mol)
Raw materials of SQ16: phenyltrimethoxysilane (0.18 mol)/octyltrimethoxysilane (0.12 mol)

All of the silsesquioxane polymers SQ1 to SQ8 included a partial structure represented by Formula (T2) and a partial structure represented by Formula (T3).

R¹—Si(—OX)O_{2/2} (T2)

R¹—SiO_{3/2} (T3)
SQ1: In Formula (T2) and Formula (T3), R¹ is a methyl group.
SQ2: In Formula (T2) and Formula (T3), R¹ is a phenyl group.
SQ3: In Formula (T2) and Formula (T3), R¹ is a vinyl group.
SQ4: In Formula (T2) and Formula (T3), R¹ is an allyl group.
SQ5: In Formula (T2) and Formula (T3), R¹ is a styryl group.
SQ6: In Formula (T2) and Formula (T3), R¹ is a 3-maleimidepropyl group.
SQ7: In Formula (T2) and Formula (T3), R¹ is a 2-(3,4-epoxycyclohexyl)ethyl group.
SQ8: In Formula (T2) and Formula (T3), R¹ is a methacryloyloxypropyl group.

All of the silsesquioxane polymers SQ9 to SQ16 included the partial structure represented by Formula (T2k) and Formula (2m), and the partial structures represented by Formula (T3k) and Formula (T3m).

R¹¹—Si(—OX)O_{2/2} (T2k)

R¹²—Si(—OX)O_{2/2} (T2m)

R¹¹—SiO_{3/2} (T3k)

R¹²—SiO_{3/2} (T3m)
SQ9: In Formula (T2k) and Formula (T3k), R¹¹ is a styryl group, and in Formula (T2m) and Formula (T3m), R¹² is a decyl group.
SQ10: In Formula (T2k) and Formula (T3k), R¹¹ is a styryl group, and in Formula (T2m) and Formula (T3m), R¹² is a decyl group.
SQ11: In Formula (T2k) and Formula (T3k), R¹¹ is a styryl group, and in Formula (T2m) and Formula (T3m), R¹² is a hexyl group.
SQ12: In Formula (T2k) and Formula (T3k), R¹¹ is a vinyl group, and in Formula (T2m) and Formula (T3m), R¹² is a decyl group.
SQ13: In Formula (T2k) and Formula (T3k), R¹¹ is a phenyl group, and in Formula (T2m) and Formula (T3m), R¹² is a hexyl group.
SQ14: In Formula (T2k) and Formula (T3k), R¹¹ is a phenyl group, and in Formula (T2m) and Formula (T3m), R¹² is an octyl group.
SQ15: In Formula (T2k) and Formula (T3k), R¹¹ is a phenyl group, and in Formula (T2m) and Formula (T3m), R¹² is a hexyl group.
SQ16: In Formula (T2k) and Formula (T3k), R¹¹ is a phenyl group, and in Formula (T2m) and Formula (T3m), R¹² is an octyl group.

### <Silicone Resin>

S1: dimethylpolysiloxane

### <Thermoplastic Resin>

P2: styrene-ethylene-butylene-styrene block copolymer, product name “TUFTEC M1913”, manufactured by Asahi Kasei Corporation

### <Thermosetting Resin>

T1: bismaleimide resin, product name “MIR-3000”, manufactured by Nippon Kayaku Co., Ltd.

### <Polymerization Initiator (Thermal Radical Polymerization Initiator)>

V1: cumene hydroperoxide

### <Filler>

F1: silica particles, product name “SC2500-SPJ”, manufactured by Admatechs Co., Ltd.
F2: Polytetrafluoroethylene (PTFE) resin particles, product name “TF-9205”, manufactured by 3M Company

Next, in order to produce a multilayer film and a bonding sheet, a solution for forming a layer A, a solution for forming a layer B, and a solution for forming a layer C were prepared. The bonding sheet was produced using the solution for forming the layer B.

### —Preparation of Solution for Forming Layer A—

The polymer and the filler shown in Table 1 were mixed together at the contents (% by mass) shown in Table 1, N-methylpyrrolidone was added thereto, and the concentration of solid contents was adjusted to 25% by mass, thereby obtaining a solution for forming a layer A.

### —Preparation of Solution for Forming Layer B—

The silsesquioxane polymer, other resins (thermoplastic resin and thermosetting resin), polymerization initiator, and filler shown in Table 2 were mixed together at the contents (% by mass) shown in Table 2, methyl isobutyl ketone was added thereto, and the concentration of solid contents was adjusted to 50% by mass, thereby obtaining a solution for forming a layer B.

### —Preparation of Solution for Forming Layer C—

8 parts of aromatic polyester amide P1 was added to 92 parts of N-methylpyrrolidone, and the mixture was stirred at 140° C. for 4 hours in a nitrogen atmosphere to obtain an aromatic polyester amide solution P1 (concentration of solid contents: 8% by mass).

0.04 parts by mass of an aminophenol-type epoxy resin (product name “jER630”, manufactured by Mitsubishi Chemical Corporation) was mixed with the aromatic polyester amide solution P1 (10.0 parts by mass) to prepare a solution for forming a layer C.

### [Preparation of Single-Sided Copper-Clad Multilayer Film]

The solution for forming a layer C was applied to a treated surface of a copper foil (manufactured by Fukuda Metal Foil & Powder Co., Ltd., CF-T4X-SV-18, thickness: 18 m, surface roughness Rz of the attached surface (treated surface): 0.85 m) using an applicator, and blast-dried at 150° C. for 1 hour. The film thickness of the layer C after drying was 3 μm. The solution for forming a layer A was applied to the obtained layer C using an applicator, and the layer C was blast-dried at 50° C. for 3 hours. Thereafter, an annealing treatment was performed at 300° C. for 3 hours in a nitrogen atmosphere. The film thickness of the layer A was as shown in Table 1. A solution for forming a layer B was applied to the obtained layer A using an applicator, and the layer A was blast-dried at 90° C. for 2 hours to obtain a laminate (single-sided copper-clad multilayer film) having a copper layer, a layer C, a layer A, and a layer B in this order.

### [Preparation of Bonding Sheet]

The solution for forming the layer B was applied to the polytetrafluoroethylene sheet using an applicator and was blast-dried at 90° C. for 2 hours. Thereafter, the bonding sheet was obtained by peeling off the bonding sheet from the polytetrafluoroethylene sheet.

### [Preparation of Wiring Board]

—Preparation of Substrate with Wiring Pattern—

A copper foil (product name “CF-T9DA-SV-18”, average thickness: 18 m, manufactured by Fukuda Metal Foil & Powder Co., Ltd.) and a liquid crystal polymer film (product name “CTQ-50”, average thickness: 50 μm, manufactured by Kuraray Co., Ltd.) as a substrate were produced. The copper foil, the substrate, and the copper foil were laminated in this order such that the treated surface of the copper foil was in contact with the substrate. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a thermal compression machine (product name “MP-SNL”, manufactured by Toyo Seiki Seisaku-sho, Ltd.), the obtained double-sided copper-clad laminated plate precursor was thermally compression-bonded for 10 minutes under conditions of 300° C. and 4.5 MPa to prepare a double-sided copper-clad laminated plate.

Each of the copper foils on both surfaces of the above-described double-sided copper-clad laminated plate was etched to perform patterning, and a substrate with wiring patterns including a ground line and three pairs of signal lines on both sides of the substrate was prepared. A length of the signal line was 50 mm, and a width of the signal line was set such that characteristic impedance was 50Ω.

### —Preparation Method a of Wiring Board—

In Examples 1 to 18 and Examples 22 to 33, a wiring board was produced using the above-described single-sided copper-clad multilayer film.

The obtained single-sided copper-clad multilayer film was superimposed with the above-described substrate with a wiring pattern on the layer B side, and subjected to a heat press for 1 hour under the conditions of 160° C. and 4 MPa, thereby obtaining a wiring board.

In the obtained wiring board, the wiring patterns (the ground line and the signal line) were embedded, and the thickness of the wiring patterns was 18 μm.

### —Preparation Method B of Wiring Board—

In Examples 19 to 21, a wiring board was prepared using the above-described bonding sheet.

The obtained solution for forming a layer C was applied to a treated surface of a copper foil (manufactured by Fukuda Metal Foil & Powder Co., Ltd., CF-T4X-SV-18, thickness: 18 m, surface roughness Rz of the attached surface (treated surface): 0.85 m) using an applicator, and blast-dried at 150° C. for 1 hour. The film thickness of the layer C after drying was 3 μm. The solution for forming a layer A was applied to the obtained layer C using an applicator, and the layer was blast-dried at 50° C. for 3 hours. Thereafter, an annealing treatment was performed at 300° C. for 3 hours in a nitrogen atmosphere. The film thickness of the layer A was as shown in Table 1. The obtained layer A was placed on the above-described bonding sheet, the above-described substrate with a wiring pattern was further superimposed on the bonding sheet, and the obtained laminate was subjected to a heat press for 1 hour under the conditions of 160° C. and 4 MPa to obtain a wiring board.

A wiring pattern (ground line and signal line) was embedded in the wiring board, and the thickness of the wiring pattern was 18 μm.

### <<Evaluation>>

The prepared single-sided copper-clad multilayer films and bonding sheets were subjected to the following measurement and evaluation, and the results are shown in Table 3.

### <<Measurement Method>>

### [Elastic Modulus of Single-Sided Copper-Clad Multilayer Film at 160° C.]

The elastic modulus of the layer B of the single-sided copper-clad multilayer film was measured as an indentation elastic modulus using a nanoindentation method. The indentation elastic modulus was measured by using a microhardness meter (product name “DUH-W201”, manufactured by Shimadzu Corporation) to apply a load at a loading rate of 0.28 mN/see with a Vickers indenter at 160° C., holding a maximum load of 10 mN for 10 seconds, and then unloading at a loading rate of 0.28 mN/sec.

### [Elastic Modulus of Bonding Sheet at 160° C.]

Using a rheometer (product name “RS6000”, manufactured by EKO Instruments Co., Ltd.), a storage elastic modulus of the bonding sheet at 160° C. was measured under the following conditions. In the bonding sheet in the single-sided copper-clad multilayer film, the measurement was performed by peeling off the bonding sheet portion. The samples were superimposed so that the thickness was about 0.1 mm. The elastic modulus at a point in time of 5 minutes from the start of measurement was read, and the average value of the n=3 measurements was calculated.
Force control mode: (Fn=2N)
Frequency: 1 Hz
Strain: 0.2%
Temperature: constant at 160° C.
Measurement time: 15 minutes

### [Storage Elastic Moduli A and B]

Using a rheometer (product name “RS6000”, manufactured by EKO Instruments Co., Ltd.), a storage elastic modulus of the bonding sheet was measured under the following conditions. Regarding the layer B of the single-sided copper-clad multilayer film, only the layer B was cut out and taken out for measurement. The samples were superimposed so that the thickness was about 0.1 mm. The elastic modulus at each temperature was read, and the average value of the measurements at n=3 was calculated.
Force control mode: (Fn=2N)
Frequency: 1 Hz
Strain: 0.2%
Temperature: 25° C. to 250° C.
Temperature rising rate: 5° C./min

### [Storage Elastic Moduli C and D]

Using a rheometer (product name “RS6000”, manufactured by EKO Instruments Co., Ltd.), a storage elastic modulus of the silsesquioxane polymer was measured under the following conditions. The silsesquioxane polymer after volatilization of the solvent was used to be superimposed so that the sample thickness was about 0.1 mm. The elastic modulus at each temperature was read, and the average value of the measurements at n=3 was calculated.
Force control mode: (Fn=2N)
Frequency: 1 Hz
Strain: 0.2%
Temperature: 25° C. to 250° C.
Temperature rising rate: 5° C./min

### [Storage Elastic Modulus a at 25° C. To 40° C.]

In the layer B or the bonding sheet of the single-sided copper-clad multilayer film, a storage elastic modulus A at 25° C. to 40° C. was evaluated. Specifically, it was determined whether or not the storage elastic modulus A was within a specific numerical value range at any temperature from 25° C. to 40° C. The evaluation standard was as follows.
A: The storage elastic modulus A at any temperature from 25° C. to 40° C. is 5×10⁶ Pa to 5×10⁷ Pa.
B: The storage elastic modulus A at any temperature from 25° C. to 40° C. is 10⁶ Pa to 10⁸ Pa, which does not correspond to the evaluation A.
C: The storage elastic modulus A at any temperature from 25° C. to 40° C. is 10⁴ Pa to 10⁸ Pa, which does not correspond to the evaluations A and B.
D: The result does not correspond to any of the evaluations A to C.

### [Storage Elastic Modulus B at 150° C. To 250° C.]

In the layer B or the bonding sheet of the single-sided copper-clad multilayer film, a storage elastic modulus B at 150° C. to 250° C. was evaluated. Specifically, it was determined whether or not the storage elastic modulus B was within a specific numerical value range at any temperature from 150° C. to 250° C. The evaluation standard was as follows.
A: The storage elastic modulus B at any temperature from 150° C. to 250° C. is 10⁵ Pa or less.
B: The storage elastic modulus B at any temperature from 150° C. to 250° C. is 3×10⁵ Pa or less, which does not correspond to the evaluation A.
C: The storage elastic modulus B at any temperature from 150° C. to 250° C. is 10⁶ Pa or less, which corresponds to neither the evaluation A nor the evaluation B.
D: The result does not correspond to any of the evaluations A to C.

### [Storage Elastic Modulus C at 25° C. To 40° C.]

In the silsesquioxane polymer, the storage elastic modulus C at 25° C. to 40° C. was evaluated. Specifically, it was determined whether or not the storage elastic modulus C was within a specific numerical value range at any temperature from 25° C. to 40° C. The evaluation standard is the same as the storage elastic modulus A.

### [Storage Elastic Modulus D at 150° C. To 250° C.]

In the silsesquioxane polymer, the storage elastic modulus D at 150° C. to 250° C. was evaluated. Specifically, it was determined whether or not the storage elastic modulus D was within a specific numerical value range at any temperature from 150° C. to 250° C. The evaluation standard is the same as the storage elastic modulus B.

### [Dielectric Loss Tangent]

The dielectric loss tangent of the single-sided copper-clad multilayer film and the wiring board was measured using a film obtained by removing a copper foil of a copper-clad laminated plate with an aqueous solution of ferric chloride, and then drying the copper foil after washing with pure water. Regarding the bonding sheet, the bonding sheet itself was used for measurement.

The dielectric loss tangent was measured by a resonance perturbation method at a frequency of 28 GHz. A 28 GHz cavity resonator (“CP531” manufactured by Kanto Electronic Application & Development Inc.) is connected to a network analyzer (“E8363B” manufactured by Agilent Technologies, Inc.), a measurement sample is inserted into the cavity resonator, and the dielectric loss tangent of the measurement sample is measured from change in resonance frequency before and after the insertion for 96 hours in an environment of a temperature of 25° C. and humidity of 60% RH.

### [Step Followability]

### —Wiring Board Prepared in Preparation Method a of Wiring Board—

The wiring board was cut along the thickness direction with a microtome, and a cross section was observed with an optical microscope. The length L1 of the gap generated in the in-plane direction between the layer B and the wiring pattern was measured. The average value of the results at 10 sites was calculated.

### —Wiring Board Prepared in Preparation Method B of Wiring Board—

The wiring board was cut along the thickness direction with a microtome, and a cross section was observed with an optical microscope. The length L1 of the gap generated in the in-plane direction between the bonding sheet and the wiring pattern was measured. The average value of the results at 10 sites was calculated.
A: L1 is less than 2 μm.
B: L1 is 2 μm or more and less than 4 μm.
C: L1 is 4 μm or more.

### [Heat Resistance A: Solder Immersion Test]

The wiring board was cut out to a size of 30 mm×30 mm and used as an evaluation sample. The evaluation sample was immersed in the hot solder at 288° C. for 10 seconds, three times. The evaluation sample after the immersion was cut with a razor, the cross section was observed with an optical microscope, and the peeling state was evaluated based on the following evaluation standards.
A: No peeling was recognized.
B: Peeling was recognized with a width of 1 mm or less.
C: Peeling was recognized with a width of more than 1 mm.

### [Heat Resistance B: Reflow Simulation Test]

The wiring board was cut out to a size of 30 mm×30 mm and used as an evaluation sample. The evaluation sample was treated in a constant temperature and humidity tank at a temperature of 85° C. and a relative humidity of 85% for 168 hours. Thereafter, the evaluation sample was placed in an oven set to 260° C. and heated for 15 minutes. The evaluation sample after heating was cut with a razor, and the cross section was observed with an optical microscope to evaluate the peeling state.
A: No peeling was recognized.
B: Peeling was recognized with a width of 1 mm or less.
C: Peeling was recognized with a width of more than 1 mm.

### [Heat Resistance C: Reflow Simulation Test]

The wiring board was cut out to a size of 30 mm×30 mm and used as an evaluation sample. The evaluation sample was treated in a constant temperature and humidity tank at a temperature of 85° C. and a relative humidity of 95% for 168 hours. Thereafter, the evaluation sample was placed in an oven set to 260° C. and heated for 15 minutes. The evaluation sample after heating was cut with a razor, and the cross section was observed with an optical microscope to evaluate the peeling state.
A: No peeling was recognized.
B: Peeling was recognized with a width of 1 mm or less.
C: Peeling was recognized with a width of more than 1 mm.

In the table, SQ means a silsesquioxane polymer. “T3/T2” means a molar ratio of a partial structure represented by Formula (T3) to a partial structure represented by Formula (T2) in the silsesquioxane polymer contained in the layer B or the bonding sheet of the single-sided copper-clad multilayer film. “T3a/T2a” means a molar ratio of a partial structure represented by Formula (T3a) to a partial structure represented by Formula (T2a) in the silsesquioxane polymer contained in the layer B of the wiring board.

TABLE 1

| | Wiring board | Layer A | | | | | |
|---|---|---|---|---|---|---|---|
| | preparation | Polymer | | Filler | | Thickness | Dielectric |
| | method | Kind | Content | Kind | Content | (μm) | loss tangent |
| Example 1 | A | P1 | 30 | PP-1 | 70 | 27 | 0.002 |
| Example 2 | A | P1 | 30 | PP-1 | 70 | 27 | 0.002 |
| Example 3 | A | P1 | 30 | PP-1 | 70 | 27 | 0.002 |
| Example 4 | A | P1 | 30 | PP-1 | 70 | 27 | 0.002 |
| Example 5 | A | P1 | 30 | PP-1 | 70 | 27 | 0.002 |
| Example 6 | A | P1 | 30 | PP-1 | 70 | 27 | 0.002 |
| Example 7 | A | P1 | 30 | PP-1 | 70 | 27 | 0.002 |
| Example 8 | A | P1 | 30 | PP-1 | 70 | 27 | 0.002 |
| Example 9 | A | P1 | 30 | PP-1 | 70 | 27 | 0.002 |
| Example 10 | A | P1 | 30 | PP-1 | 70 | 27 | 0.002 |
| Example 11 | A | P1 | 30 | PP-1 | 70 | 27 | 0.002 |
| Example 12 | A | P1 | 30 | PP-1 | 70 | 27 | 0.002 |
| Example 13 | A | P1 | 30 | PP-1 | 70 | 27 | 0.002 |
| Example 14 | A | P1 | 30 | PP-1 | 70 | 27 | 0.002 |
| Example 15 | A | P1 | 30 | PP-1 | 70 | 27 | 0.002 |
| Example 16 | A | P6 | 100 | — | — | 27 | 0.003 |
| Example 17 | A | P1 | 30 | PP-1 | 70 | 20 | 0.002 |
| Example 18 | A | P1 | 30 | PP-2 | 70 | 27 | 0.004 |
| Example 19 | B | P1 | 30 | PP-1 | 70 | 27 | 0.002 |
| Example 20 | B | P1 | 30 | PP-1 | 70 | 27 | 0.002 |
| Example 21 | B | P1 | 30 | PP-1 | 70 | 27 | 0.002 |
| Example 22 | A | P1 | 30 | PP-1 | 70 | 27 | 0.002 |
| Example 23 | A | P1 | 30 | PP-1 | 70 | 27 | 0.002 |
| Example 24 | A | P1 | 30 | PP-1 | 70 | 27 | 0.002 |
| Example 25 | A | P1 | 30 | PP-1 | 70 | 27 | 0.002 |
| Example 26 | A | P1 | 30 | PP-1 | 70 | 27 | 0.002 |
| Example 27 | A | P1 | 30 | PP-1 | 70 | 27 | 0.002 |
| Example 28 | A | P1 | 30 | PP-1 | 70 | 27 | 0.002 |
| Example 29 | A | P1 | 30 | PP-1 | 70 | 27 | 0.002 |
| Example 30 | A | P1 | 30 | PP-1 | 70 | 27 | 0.002 |
| Example 31 | A | P1 | 30 | PP-1 | 70 | 27 | 0.002 |
| Example 32 | A | P1 | 30 | PP-1 | 70 | 27 | 0.002 |
| Example 33 | A | P1 | 30 | PP-1 | 70 | 27 | 0.002 |
| Comparative | A | P1 | 30 | PP-1 | 70 | 27 | 0.002 |
| Example 1 | | | | | | | |
| Comparative | A | P1 | 30 | PP-1 | 70 | 27 | 0.002 |
| Example 2 | | | | | | | |

TABLE 2

| | Layer B/bonding sheet | | | | | | | | | |
|---|---|---|---|---|---|---|---|---|---|---|
| | SQ | | | | | | | | | |
| | | | | Dielectric | Elastic | Elastic | | | | Polymerization |
| | | | | loss | modulus | modulus | | Other resins | | initiator |
| | Kind | Mw | T3/T2 | tangent | C (MPa) | D (MPa) | Content | Kind | Content | Kind |
| Example 1 | SQ1 | 11000 | 60 | 0.004 | B | C | 100 | — | — | — |
| Example 2 | SQ2 | 11000 | 60 | 0.004 | B | C | 100 | — | — | — |
| Example 3 | SQ3 | 40000 | 75 | 0.004 | D | C | 97 | — | — | V1 |
| Example 4 | SQ4 | 11000 | 60 | 0.004 | B | C | 97 | — | — | V1 |
| Example 5 | SQ5 | 52000 | 80 | 0.004 | D | C | 97 | — | — | V1 |
| Example 6 | SQ6 | 66000 | 85 | 0.004 | D | C | 97 | — | — | V1 |
| Example 7 | SQ7 | 30000 | 70 | 0.007 | B | C | 97 | — | — | V1 |
| Example 8 | SQ8 | 11000 | 60 | 0.007 | B | B | 97 | — | — | V1 |
| Example 9 | SQ5 | 160000 | 85 | 0.004 | D | C | 97 | — | — | V1 |
| Example 10 | SQ5 | 9300 | 20 | 0.008 | B | C | 97 | — | — | V1 |
| Example 11 | SQ1 | 3000 | 4 | 0.009 | D | A | 97 | — | — | V1 |
| Example 12 | SQ5 | 52000 | 80 | 0.004 | D | C | 74 | P2 | 23 | V1 |
| Example 13 | SQ5 | 52000 | 80 | 0.004 | D | C | 74 | T1 | 23 | V1 |
| Example 14 | SQ5 | 52000 | 80 | 0.004 | D | C | 74 | — | — | V1 |
| Example 15 | SQ5 | 52000 | 80 | 0.004 | D | C | 74 | — | — | V1 |
| Example 16 | SQ5 | 52000 | 80 | 0.004 | D | C | 97 | — | — | V1 |
| Example 17 | SQ5 | 52000 | 80 | 0.004 | D | C | 97 | — | — | V1 |
| Example 18 | SQ5 | 52000 | 80 | 0.004 | D | C | 97 | — | — | V1 |
| Example 19 | SQ5 | 52000 | 80 | 0.004 | D | C | 97 | — | — | V1 |
| Example 20 | SQ5 | 52000 | 80 | 0.004 | D | C | 74 | P2 | 23 | V1 |
| Example 21 | SQ5 | 52000 | 80 | 0.004 | D | C | 74 | T1 | 23 | V1 |
| Example 22 | SQ9 | 17000 | >99 | 0.003 | B | B | 97 | — | — | V1 |
| Example 23 | SQ10 | 14000 | >99 | 0.002 | A | A | 97 | — | — | V1 |
| Example 24 | SQ11 | 41000 | >99 | 0.003 | B | C | 97 | — | — | V1 |
| Example 25 | SQ12 | 34000 | 99 | 0.003 | B | A | 97 | — | — | V1 |
| Example 26 | SQ13 | 11000 | 99 | 0.003 | A | A | 100 | — | — | — |
| Example 27 | SQ13 | 6000 | 99 | 0.004 | A | A | 100 | — | — | — |
| Example 28 | SQ14 | 11000 | 99 | 0.003 | C | A | 100 | — | — | — |
| Example 29 | SQ15 | 13000 | 99 | 0.003 | B | A | 100 | — | — | — |
| Example 30 | SQ16 | 11000 | 99 | 0.003 | A | A | 100 | — | — | — |
| Example 31 | SQ11 | 41000 | >99 | 0.003 | B | C | 74 | P2 | 23 | V1 |
| Example 32 | SQ13 | 11000 | 99 | 0.003 | A | A | 74 | T1 | 23 | V1 |
| Example 33 | SQ13 | 11000 | 99 | 0.003 | A | A | 74 | — | — | V1 |
| Comparative | — | — | — | — | — | — | — | P2 | 100 | — |
| Example 1 | | | | | | | | | | |
| Comparative | — | — | — | — | — | | | S1 | 100 | — |
| Example 2 | | | | | | | | | | |

| | Layer B/bonding sheet | | | | | | | |
|---|---|---|---|---|---|---|---|---|
| | | | | | | | | Storage |
| | | | | | | | | elastic |
| | Polymerization | | | | Dielectric | Elastic | Elastic | modulus |
| | initiator | Filler | | Thickness | loss | modulus | modulus | at 160° C. |
| | Content | Kind | Content | (μm) | tangent | A (MPa) | B (MPa) | (MPa) |
| Example 1 | — | — | — | 25 | 0.004 | B | C | 0.35 |
| Example 2 | — | — | — | 25 | 0.004 | B | C | 0.35 |
| Example 3 | 3 | — | — | 25 | 0.004 | D | C | 0.40 |
| Example 4 | 2 | — | — | 25 | 0.004 | B | C | 0.35 |
| Example 5 | 3 | — | — | 25 | 0.004 | D | C | 0.40 |
| Example 6 | 3 | — | — | 25 | 0.004 | D | C | 0.40 |
| Example 7 | 3 | — | — | 25 | 0.007 | B | C | 0.40 |
| Example 8 | 3 | — | — | 25 | 0.007 | B | C | 0.40 |
| Example 9 | 3 | — | — | 25 | 0.004 | D | C | 0.70 |
| Example 10 | 3 | — | — | 25 | 0.008 | B | C | 0.35 |
| Example 11 | 3 | — | — | 25 | 0.009 | D | A | 0.001 |
| Example 12 | 3 | — | — | 25 | 0.003 | C | B | 0.25 |
| Example 13 | 3 | — | — | 25 | 0.004 | C | B | 0.30 |
| Example 14 | 3 | F1 | 23 | 25 | 0.003 | D | C | 0.45 |
| Example 15 | 3 | F2 | 23 | 25 | 0.003 | D | C | 0.45 |
| Example 16 | 3 | — | — | 25 | 0.004 | D | C | 0.40 |
| Example 17 | 3 | — | — | 30 | 0.004 | D | C | 0.40 |
| Example 18 | 3 | — | — | 25 | 0.004 | D | C | 0.40 |
| Example 19 | 3 | — | — | 25 | 0.004 | D | C | 0.40 |
| Example 20 | 3 | — | — | 25 | 0.003 | C | B | 0.25 |
| Example 21 | 3 | — | — | 25 | 0.004 | C | B | 0.30 |
| Example 22 | 3 | — | — | 25 | 0.003 | B | C | 0.40 |
| Example 23 | 3 | — | — | 25 | 0.002 | A | B | 0.30 |
| Example 24 | 3 | — | — | 25 | 0.003 | B | C | 0.40 |
| Example 25 | 3 | — | — | 25 | 0.003 | B | B | 0.30 |
| Example 26 | — | — | — | 25 | 0.003 | A | A | 0.10 |
| Example 27 | — | — | — | 25 | 0.004 | A | A | 0.05 |
| Example 28 | — | — | — | 25 | 0.003 | C | A | 0.01 |
| Example 29 | — | — | — | 25 | 0.003 | B | A | 0.05 |
| Example 30 | — | — | — | 25 | 0.003 | A | A | 0.10 |
| Example 31 | 3 | — | — | 25 | 0.003 | B | B | 0.30 |
| Example 32 | 3 | — | — | 25 | 0.003 | B | C | 0.40 |
| Example 33 | 3 | F1 | 23 | 25 | 0.003 | A | B | 0.20 |
| Comparative | — | — | — | 25 | 0.002 | A | A | 0.10 |
| Example 1 | | | | | | | | |
| Comparative | — | — | — | 25 | 0.004 | D | A | 0.001 |
| Example 2 | | | | | | | | |

TABLE 3

| | Wiring board | | Evaluation | | | |
|---|---|---|---|---|---|---|
| | | Dielectric | Step | Heat | Heat | Heat |
| | SQ | loss | follow- | resis- | resis- | resis- |
| | T3a/T2a | tangent | ability | tance A | tance B | tance C |
| Example 1 | 65 | 0.0025 | A | A | B | C |
| Example 2 | 65 | 0.0025 | A | A | B | C |
| Example 3 | 80 | 0.0025 | A | A | A | B |
| Example 4 | 65 | 0.0025 | A | A | A | B |
| Example 5 | 85 | 0.0025 | A | A | A | B |
| Example 6 | 88 | 0.0025 | A | A | A | B |
| Example 7 | 75 | 0.004 | A | A | B | C |
| Example 8 | 65 | 0.004 | A | A | B | C |
| Example 9 | 88 | 0.0025 | B | A | A | B |
| Example 10 | 30 | 0.0045 | A | A | B | C |
| Example 11 | 15 | 0.0055 | A | A | B | C |
| Example 12 | 85 | 0.002 | A | A | A | B |
| Example 13 | 85 | 0.0025 | A | A | A | B |
| Example 14 | 85 | 0.002 | A | A | A | B |
| Example 15 | 85 | 0.002 | A | A | A | B |
| Example 16 | 85 | 0.003 | A | A | A | B |
| Example 17 | 85 | 0.0025 | A | A | A | B |
| Example 18 | 85 | 0.0035 | A | A | A | B |
| Example 19 | 85 | 0.0025 | A | A | A | B |
| Example 20 | 85 | 0.002 | A | A | A | B |
| Example 21 | 85 | 0.0025 | A | A | A | B |
| Example 22 | >99 | 0.002 | A | A | A | A |
| Example 23 | >99 | 0.002 | A | A | A | A |
| Example 24 | >99 | 0.002 | A | A | A | A |
| Example 25 | 99 | 0.003 | A | A | A | A |
| Example 26 | 99 | 0.002 | A | A | A | A |
| Example 27 | 99 | 0.0025 | A | A | A | B |
| Example 28 | 99 | 0.002 | A | A | A | A |
| Example 29 | 99 | 0.002 | A | A | A | A |
| Example 30 | 99 | 0.002 | A | A | A | A |
| Example 31 | >99 | 0.002 | A | A | A | A |
| Example 32 | 99 | 0.002 | A | A | A | A |
| Example 33 | 99 | 0.002 | A | A | A | A |
| Comparative | — | 0.0023 | A | C | C | C |
| Example 1 | | | | | | |
| Comparative | — | 0.0025 | A | C | C | C |
| Example 2 | | | | | | |

As shown in Table 3, in Examples 1 to 18 and 22 to 33, the laminate includes the layer A, and the layer B disposed on at least one surface of the layer A, the layer B includes the silsesquioxane polymer, and the laminates has the dielectric loss tangent of 0.01 or less. Therefore, the laminate has excellent step followability and heat resistance.

In Examples 19 to 21, since the polymer film includes a silsesquioxane polymer and has a dielectric loss tangent of 0.01 or less, the polymer film has excellent step followability and heat resistance.

On the other hand, in Comparative Examples 1 and 2, it was found that the layer B in the laminate did not contain the silsesquioxane polymer, and the heat resistance was deteriorated.

The disclosure of JP2022-197498 filed on Dec. 9, 2022 and the disclosure of JP2023-087306 filed on May 26, 2023 are incorporated in the present specification by reference. In addition, all documents, patent applications, and technical standards described in the present specification are herein incorporated by reference to the same extent that each individual document, patent application, or technical standard was specifically and individually indicated to be incorporated by reference.

What is claimed is:

1. A polymer film comprising:
a silsesquioxane polymer,
wherein the polymer film has a dielectric loss tangent of 0.01 or less.

2. The polymer film according to claim 1,
wherein the polymer film has a dielectric loss tangent of 0.005 or less.

3. The polymer film according to claim 1,
wherein the polymer film has a dielectric loss tangent of 0.003 or less.

4. The polymer film according to claim 1,
wherein the polymer film has a storage elastic modulus at 160° C. of 0.5 MPa or less.

5. The polymer film according to claim 1,
wherein the polymer film has
a storage elastic modulus A at any temperature from 25° C. to 40° C. of 10⁴ Pa to 10⁸ Pa, and
a storage elastic modulus B at any temperature from 150° C. to 250° C. of 10⁶ Pa or less.

6. The polymer film according to claim 5,
wherein the storage elastic modulus A is 10⁶ Pa to 10⁸ Pa, and the storage elastic modulus B is 3×10 Pa or less.

7. The polymer film according to claim 1, further comprising:
a thermoplastic resin or a thermosetting resin other than the silsesquioxane polymer.

8. The polymer film according to claim 1, further comprising:
an inorganic filler.

9. A laminate comprising:
a layer A; and
a layer B disposed on at least one surface of the layer A,
wherein the layer B contains a silsesquioxane polymer, and
the laminate has a dielectric loss tangent of 0.01 or less.

10. The laminate according to claim 9,
wherein the layer A contains a liquid crystal polymer.

11. A silsesquioxane polymer,
wherein the silsesquioxane polymer has a dielectric loss tangent of 0.01 or less.

12. The silsesquioxane polymer according to claim 11,
wherein the silsesquioxane polymer has a weight-average molecular weight of 4,000 or more.

13. The silsesquioxane polymer according to claim 11,
wherein the silsesquioxane polymer has a dielectric loss tangent of 0.005 or less.

14. The silsesquioxane polymer according to claim 11,
wherein the silsesquioxane polymer has a dielectric loss tangent of 0.003 or less.

15. The silsesquioxane polymer according to claim 11,
wherein the silsesquioxane polymer includes a partial structure represented by Formula (T2) and a partial structure represented by Formula (T3), and a molar ratio of the partial structure represented by Formula (T3) to the partial structure represented by Formula (T2) is 50 or more,
R¹—Si(—OX)O_{2/2} (T2)
R¹—SiO_{3/2} (T3)
in Formula (T2) and Formula (T3), R¹'s each independently represent an organic group, and X represents a hydrogen atom or an alkyl group having 1 to 6 carbon atoms.

16. The silsesquioxane polymer according to claim 15,
wherein the partial structure represented by Formula (T3) includes a partial structure represented by Formula (T3k) and a partial structure represented by Formula (T3m), and a molar ratio of the partial structure represented by Formula (T3m) to the partial structure represented by Formula (T3k) is 0.01 to 99,
R¹¹—SiO_{3/2} (T3k)
R¹²—SiO_{3/2} (T3m)
in Formula (T3k), R¹¹ is an unsubstituted aromatic hydrocarbon group, an aromatic hydrocarbon group having a substituent, or a vinyl group,
in Formula (T3m), R¹² is an aliphatic hydrocarbon group having a C log P value of 2.5 or more.

17. The silsesquioxane polymer according to claim 16,
wherein R¹² is an unsubstituted aliphatic hydrocarbon group having 4 or more carbon atoms, or an aliphatic hydrocarbon group, which has a substituent, having 4 or more carbon atoms.

18. The silsesquioxane polymer according to claim 11, further comprising:
a crosslinkable group.

19. The silsesquioxane polymer according to claim 18,
wherein the crosslinkable group is at least one selected from the group consisting of a vinyl group, an allyl group, a styryl group, and a maleimide group.

20. The silsesquioxane polymer according to claim 16,
wherein R¹¹ is a styryl group, and R¹² is an unsubstituted aliphatic hydrocarbon group having 6 or more carbon atoms.

21. The silsesquioxane polymer according to claim 11,
wherein the silsesquioxane polymer has a storage elastic modulus C at any temperature from 25° C. to 40° C. of 10⁴ Pa to 10⁸ Pa, and a storage elastic modulus D at any temperature from 150° C. to 250° C. of 3×10⁵ Pa or less.

22. The silsesquioxane polymer according to claim 16,
wherein R¹¹ is a phenyl group, and R¹² is an unsubstituted aliphatic hydrocarbon group having 6 or more carbon atoms.
